(19) United States
(12) Patent Application Publication
(10) Pub. No.: US 2024/0204107 A1
(43) Pub. Date: Jun. 20, 2024

(54) SEMICONDUCTOR DEVICE

(71) Applicant: SAMSUNG ELECTRONICS CO., LTD., SUWON-SI (KR)

(72) Inventors: Sang Koo KANG, Suwon-si (KR); Woo Kyung YOU, Suwon-si (KR); Min Jae KANG, Suwon-si (KR); Koung Min RYU, Suwon-si (KR); Hoon Seok SEO, Suwon-si (KR); Woo Jin LEE, Suwon-si (KR); Jun Chae LEE, Suwon-si (KR)

(21) Appl. No.: 18/532,230

(22) Filed: Dec. 7, 2023

(30) Foreign Application Priority Data
Dec. 19, 2022 (KR) 10-2022-0178345

(51) Int. Cl. H01L 29/786; H01L 27/088; H01L 29/417; H01L 29/66

(52) U.S. Cl. CPC H01L 29/7869; H01L 27/0886; H01L 29/41733; H01L 29/66742; H01L 29/66795; H01L 29/78618; H01L 29/78696

(57) ABSTRACT

A semiconductor device includes: a substrate including an upper side and a lower side; first and second active patterns spaced apart from each other; a field insulating film covering side walls of the first and second active patterns; a power rail disposed adjacent to a first side wall of the second active pattern and between the first active pattern and the second active pattern; a power rail via disposed on the power rail and connected to the power rail; a semiconductor etching stop pattern disposed adjacent to a second side wall of the second active pattern; and a first semiconductor pattern disposed on the semiconductor etching stop pattern, wherein a lower surface of the semiconductor etching stop pattern is disposed on substantially a same plane as the lower side of the substrate, and wherein at least part of the first semiconductor pattern is disposed in the field insulating film.

### CROSS-REFERENCE TO RELATED APPLICATION

This application claims priority under 35 USC § 119 to Korean Patent Application No. 10-2022-0178345 filed on Dec. 19, 2022 in the Korean Intellectual Property Office, the disclosure of which is incorporated by reference herein in its entirety.

### TECHNICAL FIELD

The present disclosure relates to a semiconductor device.

### DISCUSSION OF THE RELATED ART

As one of scaling technologies for increasing density of semiconductor devices, a multi gate transistor has been under development. Generally, the multi gate transistor may include a multi-channel active pattern (or, e.g., a silicon body) having a fin or nanowire shape, which is formed on a substrate, and a gate that is formed on a surface of the multi-channel active pattern.

Since such a multi gate transistor utilizes a three-dimensional channel, scaling may be easily performed. Further, even if a gate length of the multi gate transistor is not increased, the current control capability may be increased. Furthermore, a SCE (short channel effect), in which potential of a channel region is influenced by a drain voltage, may be suppressed.

In addition, as a pitch size of the semiconductor device decreases, there is a desire for research for reducing the capacitance between contacts in the semiconductor device and ensuring electrical stability.

### SUMMARY

According to an embodiment of the present inventive concept, a semiconductor device includes: a substrate which includes an upper side and a lower side that are opposite to each other; first and second active patterns which each extend in a first direction and are spaced apart from each other in a second direction; a field insulating film which covers side walls of the first and second active patterns; a power rail which is disposed adjacent to a first side wall of the second active pattern and between the first active pattern and the second active pattern; a power rail via which is disposed on the power rail and connected to the power rail; a semiconductor etching stop pattern which is disposed adjacent to a second side wall of the second active pattern; and a first semiconductor pattern disposed on the semiconductor etching stop pattern, wherein a lower surface of the semiconductor etching stop pattern is disposed on substantially a same plane as the lower side of the substrate, and wherein at least part of the first semiconductor pattern is disposed in the field insulating film.

According to an embodiment of the present inventive concept, a semiconductor device includes: a substrate which includes an upper side and a lower side that are opposite to each other; a lower insulating film which is disposed on the lower side of the substrate; first to third active patterns which each extend in a first direction and are sequentially aligned in a second direction; a field insulating film which covers side walls of the first to third active patterns; a plurality of gate electrodes which cover the first to third active patterns, and extend in the second direction, wherein the plurality of gate electrodes are spaced apart from each other in the first direction, on the field insulating film; a first source/drain pattern which is disposed between the plurality of gate electrodes, on the first active pattern; a second source/drain pattern which is disposed between the plurality of gate electrodes, on the second active pattern; a power rail which penetrates the lower insulating film and is disposed between the first active pattern and the second active pattern; a power rail via which is disposed between the plurality of gate electrodes, and between the first source/drain pattern and the second source/drain pattern, wherein the power rail via is disposed on the power rail and is connected to the power rail; a first semiconductor etching stop pattern which is disposed between the second active pattern and the third active pattern; and a semiconductor pattern disposed on the first semiconductor etching stop pattern, wherein a first spaced distance in the second direction between the first active pattern and the second active pattern is greater than a second spaced distance in the second direction between the second active pattern and the third active pattern, a lower surface of the first semiconductor etching stop pattern is disposed on the lower insulating film, and at least part of the semiconductor pattern overlaps the field insulating film.

According to an embodiment of the present inventive concept, a semiconductor device includes: a substrate which includes an upper side and a lower side that are opposite to each other; first and second active patterns which include first and second lower patterns, each of which extend in a first direction and are spaced apart from each other in a second direction, and first and second sheet patterns, which are spaced apart from each of the first and second lower patterns in a third direction, on the upper side of the substrate; a field insulating film which covers side walls of the first and second lower patterns and is disposed on the upper side of the substrate; a plurality of gate electrodes which wrap around the first and second sheet patterns on the first and second lower patterns, and extend in the second direction, wherein the plurality of gate electrodes are spaced apart from each other in the first direction; a first source/drain pattern which is connected to the first sheet pattern and is disposed between the plurality of gate electrodes, on the first lower pattern; a second source/drain pattern which is connected to the second sheet pattern and is disposed between the plurality of gate electrodes, on the second lower pattern; a power rail which is placed between the first lower pattern and the second lower pattern, on the lower side of the substrate; a power rail via which is placed between the first and second source/drain patterns and between the plurality of gate electrodes, wherein the power rail via is connected to the power rail; a semiconductor etching stop pattern which is placed adjacent to a first side wall of the second lower pattern that is opposite to a second sidewall of the second lower pattern that faces the first lower pattern; and a semiconductor pattern disposed on the semiconductor etching stop pattern, wherein a lower surface of the semiconductor etching stop pattern is placed on substantially a same plane as the lower side of the substrate, at least a part of the semiconductor pattern overlaps the field insulating film in the third direction, and the semiconductor etching stop pattern and the semiconductor pattern are formed of different materials from each other.

### BRIEF DESCRIPTION OF THE DRAWINGS

The above and features of the present inventive concept will become more apparent by describing in detail exemplary embodiments thereof with reference to the attached drawings, in which:

FIG. 1 is an exemplary layout diagram for illustrating a semiconductor device according to some embodiments of the present inventive concept.

FIG. 2 is a cross-sectional view taken along a line A-A′ of FIG. 1.

FIG. 3 is a cross-sectional view taken along a line B-B′ of FIG. 1.

FIG. 4 is a cross-sectional view taken along a line C-C′ of FIG. 1.

FIGS. 5, 6, 7, 8, 9 and 10 are diagrams illustrating a semiconductor device according to some embodiments of the present inventive concept.

FIGS. 11, 12, 13 and 14 are diagrams illustrating a semiconductor device according to some embodiments of the present inventive concept.

FIGS. 15, 16, 17, 18, 19, 20, 21, 22, 23, 24, 25, 26, 27 and 28 are intermediate step diagrams illustrating a method of manufacturing a semiconductor device according to some embodiments of the present inventive concept.

### DETAILED DESCRIPTION OF THE EMBODIMENTS

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

Although drawings of a semiconductor device according to some embodiments of the present inventive concept show a fin-type transistor (FinFET) including a channel region of a fin-type pattern shape, a transistor including a nanowire or a nanosheet, a MBCFET™ (Multi-Bridge Channel Field Effect Transistor) or a vertical transistor (Vertical FET) as an example, the present inventive concept is not limited thereto. The semiconductor device according to some embodiments of the present inventive concept may include, for example, a tunneling transistor (tunneling FET) or a three-dimensional (3D) transistor. The semiconductor device according to some embodiments of the present inventive concept may include, for example, a planar transistor. In addition, the technical idea of the present inventive concept may be applied to a transistor based on two-dimensional material (2D maternal based FETs) and a heterostructure thereof.

Further, the semiconductor device according to some embodiments of the present inventive concept may also include, for example, a bipolar junction transistor, a laterally diffused metal oxide semiconductor (LDMOS), or the like.

Hereinafter, embodiments of the present inventive concept will be described with reference to the accompanying drawings.

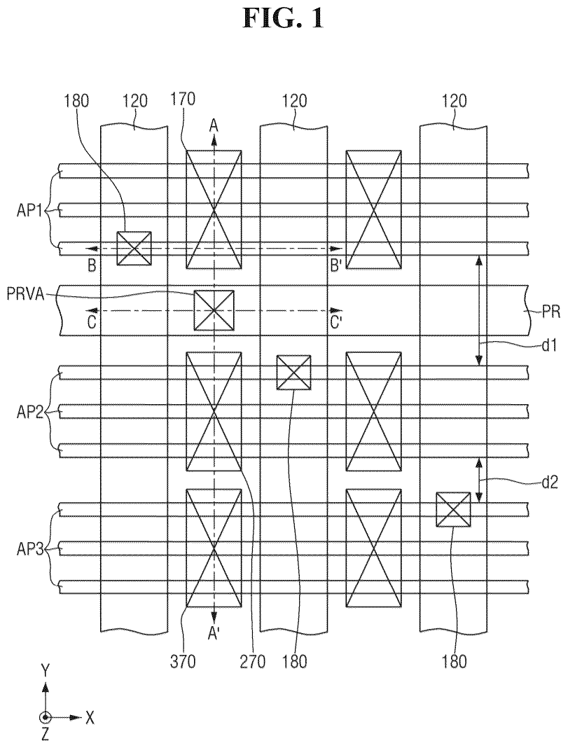

First, a semiconductor device according to some embodiments of the present inventive concept will be described with reference to FIGS. 1 to 4.

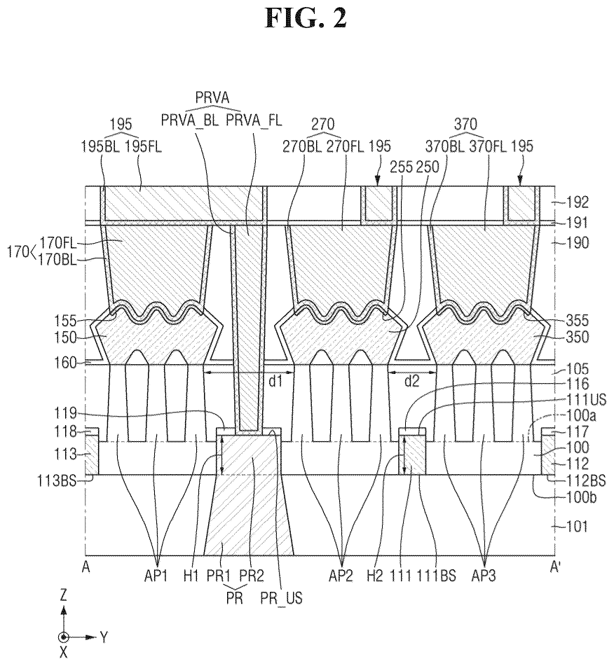

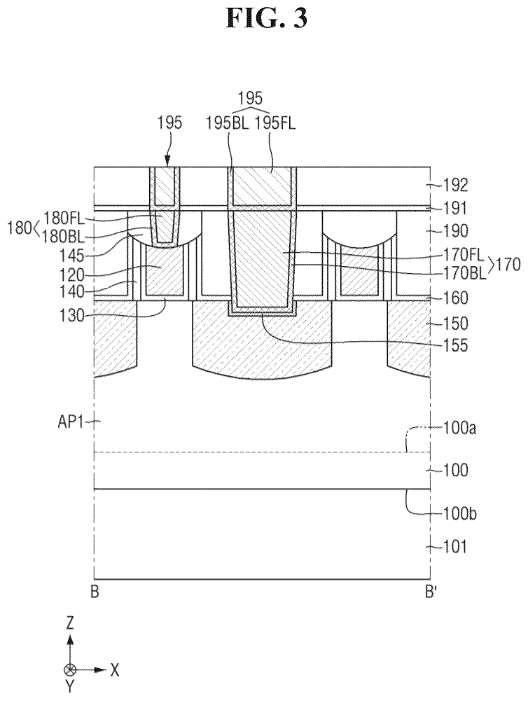

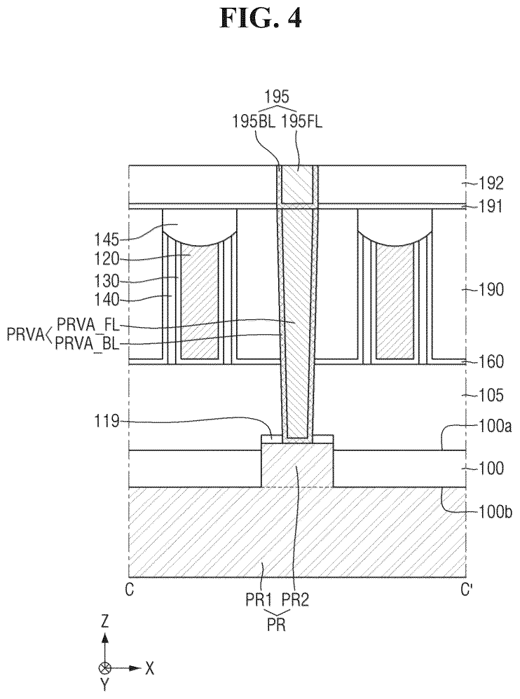

FIG. 1 is a layout diagram illustrating a semiconductor device according to some embodiments of the present inventive concept. FIG. 2 is a cross-sectional view taken along a line A-A′ of FIG. 1. FIG. 3 is a cross-sectional view taken along a line B-B′ of FIG. 1. FIG. 4 is a cross-sectional view taken along a line C-C′ of FIG. 1.

Referring to FIGS. 1 to 4, a semiconductor device according to some embodiments of the present inventive concept includes at least one or more first active patterns AP1, at least one or more second active patterns AP2, at least one or more third active patterns AP3, a plurality of gate electrodes 120, a first source/drain contact 170, a second source/drain contact 270, a third source/drain contact 370, a gate contact 180, a power rail PR, a power rail via PRVA.

The substrate 100 may include a plurality of active regions and a field region. Each of the plurality of active regions may be a region in which the first active pattern AP 1, the second active pattern AP2 or the third active pattern AP3 is placed. The field region may be formed to be adjacent to the plurality of active regions. The field region may form a boundary with the plurality of active regions.

The plurality of active regions are spaced apart from each other. The plurality of active regions may be separated by the field region. In other words, an element isolation film may be placed around a plurality of active regions spaced apart from each other. In addition, a portion of the element isolation film located between the plurality of active regions may be the field region. For example, a portion in which a channel region of a transistor, which may be an example of the semiconductor device, is formed may be the active region, and a portion which divides the channel region of the transistor formed in the active region may be the field region. In addition, the active region may be a portion in which the fin-type pattern or nanosheet used as the channel region of the transistor is formed, and the field region may be a region in which the fin-type pattern or nanosheet used as the channel region is not formed.

A substrate 100 may be provided. The substrate 100 may include an upper side 100a and a lower side 100b that are opposite to each other in a third direction Z. The substrate 100 may be, for example, a silicon substrate or silicon-on-insulator (SOI). In addition, the substrate 100 may include, but is not limited to, silicon-germanium, silicon germanium on insulator (SGOI), indium antimonide, lead tellurium compounds, indium arsenic, indium phosphate, gallium arsenide or antimonide gallium.

The first active pattern AP1, the second active pattern AP2, and the third active pattern AP3 may each be placed on the upper side 100a of the substrate 100. The first active pattern AP 1, the second active pattern AP2, and the third active pattern AP3 may each extend long on the substrate 100 along the first direction X. The first active pattern AP1, the second active pattern AP2, and the third active pattern AP3 may be spaced apart from each other in the second direction Y. The first active pattern AP1, the second active pattern AP2, and the third active pattern AP3 may be sequentially arranged in a second direction Y. For example, the second active pattern AP2 may be placed between the first active pattern AP1 and the third active pattern AP3. In some embodiments of the present inventive concept, although a first spaced distance d1 in the second direction Y between the first active pattern AP1 and the second active pattern AP2 may be greater than a second spaced distance d2 in the second direction Y between the second active pattern AP2 and the third active pattern AP3, the present inventive concept is not limited thereto.

The first active pattern AP1, the second active pattern AP2, and the third active pattern AP3 may each include a long side extending in the first direction X and a short side extending in the second direction Y. Here, the first direction X may intersect the second direction Y and the third direction Z. In addition, the second direction Y may intersect the third direction Z. The third direction Z may be a thickness direction that is substantially perpendicular to the upper side 100a of the substrate 100.

Each of the first active pattern AP1, the second active pattern AP2, and the third active pattern AP3 may be a multi-channel active pattern. In the semiconductor device according to some embodiments of the present inventive concept, each of the first active pattern AP 1, the second active pattern AP2, and the third active pattern AP3 may be, for example, a fin-type pattern. The first active pattern AP1, the second active pattern AP2, and the third active pattern AP3 may each be used as channel regions of a transistor. Although three of each of first active patterns AP1, the second active patterns AP2, and the third active patterns AP3 are shown, this is only for convenience of explanation, and the present inventive concept is not limited thereto. One or more of each of the first active patterns AP1, the second active patterns AP2, and the third active patterns AP3 may be provided.

The first active pattern AP1, the second active pattern AP2, and the third active pattern AP3 may each be a part of the substrate 100, and may include an epitaxial film that is grown from the substrate 100. The first active pattern AP1, the second active pattern AP2, and the third active pattern AP3 may include, for example, silicon or germanium which is an elemental semiconductor material. In addition, the first active pattern AP1, the second active pattern AP2, and the third active pattern AP3 may include a compound semiconductor, and may include, for example, a group IV-IV compound semiconductor or a group III-V compound semiconductor.

The group IV-IV compound semiconductor may be, for example, a binary compound or a ternary compound including at least two or more of carbon (C), silicon (Si), germanium (Ge), and tin (Sn), or a compound obtained by doping these elements with a group IV element.

The group III-V compound semiconductor may be, for example, at least one of a binary compound, a ternary compound or a quaternary compound formed by combining at least one of aluminum (Al), gallium (Ga) and/or indium (In) as a group III element with one of phosphorus (P), arsenic (As) and antimony (Sb) as a group V element.

In some embodiments of the present inventive concept, the first active pattern AP1, the second active pattern AP2, and the third active pattern AP3 may each include the same material as each other. For example, the first active pattern AP1, the second active pattern AP2, and the third active pattern AP3 may each be a silicon fin-type pattern. In addition, for example, the first active pattern AP1, the second active pattern AP2, and the third active pattern AP3 may each be a fin-type pattern including a silicon-germanium pattern. As another example, the first active pattern AP1, the second active pattern AP2, and the third active pattern AP3 may include different materials from each other. For example, some of the first active pattern AP1, the second active pattern AP2, and the third active pattern AP3 may be a silicon fin-type pattern, and others thereof may be fin-type patterns including silicon-germanium patterns.

A field insulating film 105 may be formed on the substrate 100. The field insulating film 105 may be formed on the upper side 100a of the substrate 100.

The field insulating film 105 may cover side walls of the first active pattern AP1, the side walls of the second active pattern AP2, and the side walls of the third active pattern AP3. The field insulating film 105 may include, for example, an oxide film, a nitride film, an oxynitride film or a combination thereof. Although the field insulating film 105 is shown to be a single film, the present inventive concept is not limited thereto. Unlike the shown example, the field insulating film 105 may include a field liner, which extends along the side walls and a bottom surface of the fin trench, and a field filling film disposed on the field liner.

A plurality of gate electrodes 120 may be placed on the substrate 100. For example, the plurality of gate electrodes 120 may be placed on the field insulating film 105. The plurality of gate electrodes 120 may each extend in the second direction Y. The plurality of gate electrodes 120 may be spaced apart from each other in the first direction X.

The plurality of gate electrodes 120 may be placed on the first active pattern AP1, the second active pattern AP2, and the third active pattern AP3. The plurality of gate electrodes 120 may cover the first active pattern AP1, the second active pattern AP2, and the third active pattern AP3. For example, plurality of gate electrodes 120 may cover a portion of each of the first active pattern AP1, the second active pattern AP2, and the third active pattern AP3. The plurality of gate electrodes 120 may intersect the first active pattern AP1, the second active pattern AP2, and the third active pattern AP3. The plurality of gate electrodes 120 may each include long sides extending in the second direction Y, and short sides extending in the first direction X.

In FIG. 3, although the upper surface of each of the plurality of gate electrodes 120 may be a convex curved surface that is recessed toward the upper surface of the first active pattern AP1, the present inventive concept is not limited thereto. For example, unlike the shown example, the upper surface of each of the plurality of gate electrodes 120 may be a flat plane.

The plurality of gate electrodes 120 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof.

The plurality of gate electrodes 120 may each include, for example, a conductive metal oxide, a conductive metal oxynitride, and the like, and may include oxidized forms of the aforementioned materials.

The plurality of gate electrodes 120 may be placed on both sides of a first source/drain pattern 150, which will be described below. The plurality of gate electrodes 120 may be placed on both sides of the second source/drain pattern 250 or both sides of a third source/drain pattern 350.

As an example, all the gate electrodes 120 placed on both sides of the first source/drain pattern 150 may be gate electrodes used as gates of the transistor. As another example, although the gate electrode 120 placed on one side of the first source/drain pattern 150 is used as the gate of the transistor, the gate electrode 120 placed on the other side of the first source/drain pattern 150 may be a dummy gate electrode.

A plurality of gate spacers 140 may be placed on a side wall of each of the plurality of gate electrodes 120. The plurality of gate spacers 140 is not brought into contact with the plurality of gate electrodes 120. The gate insulating film 130 may be placed between the gate spacer 140 and side walls of the gate electrode 120. The plurality of gate spacers 140 may each extend in the second direction Y. The plurality of gate spacers 140 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof.

The gate insulating film 130 may extend along side walls and bottom surfaces of each of the plurality of gate electrodes 120. The gate insulating film 130 may be formed on the first active pattern AP1, the second active pattern AP2, the third active pattern AP3 and the field insulating film 105. The gate insulating film 130 may be formed between the plurality of gate electrodes 120 and the plurality of gate spacers 140.

The gate insulating film 130 may include, for example, silicon oxide, silicon oxynitride, silicon nitride or a high dielectric constant material having a dielectric constant greater than that of silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and/or lead zinc niobate.

Although the gate insulating film 130 is shown as a single film, this is only for convenience of explanation, and the present inventive concept is not limited thereto. The gate insulating film 130 may include a plurality of films. The gate insulating film 130 may include an interfacial layer and a high dielectric constant insulating film placed between the first active pattern AP1 and the gate electrode 120, between the second active pattern AP2 and the plurality of gate electrodes 120, and between the third active pattern AP3 and the plurality of gate electrodes 120.

A semiconductor device according to some embodiments of the present inventive concept may include may an NC (Negative Capacitance) FET that uses a negative capacitor. For example, the gate insulating film 130 may include a ferroelectric material film having ferroelectric properties and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. In addition, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) under about 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and/or lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include, for example, a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and/or yttrium (Y).

When the dopant is aluminum (Al), the ferroelectric material film may include about 3 to about 8 at % (atomic %) aluminum. Here, a ratio of the dopant may be a ratio of aluminum to the sum of hafnium and aluminum.

When the dopant is silicon (Si), the ferroelectric material film may include about 2 to about 10 at % silicon. When the dopant is yttrium (Y), the ferroelectric material film may include about 2 to about 10 at % yttrium. When the dopant is gadolinium (Gd), the ferroelectric material film may include about 1 to about 7 at % gadolinium. When the dopant is zirconium (Zr), the ferroelectric material film may include about 50 to about 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but is not limited to, at least one of hafnium oxide, zirconium oxide, and/or aluminum oxide.

The ferroelectric material film and the paraelectric material film may include the same material as each other. The ferroelectric material film has the ferroelectric properties, but the paraelectric material film might not have the ferroelectric properties. For example, when the ferroelectric material film and the paraelectric material film include hafnium oxide, a crystal structure of hafnium oxide included in the ferroelectric material film differs from a crystal structure of hafnium oxide included in the paraelectric material film.

The ferroelectric material film may have a thickness having the ferroelectric properties. A thickness of the ferroelectric material film may be, for example, but is not limited to, about 0.5 to about 10 nm. Since a critical thickness that exhibits the ferroelectric properties may vary for each ferroelectric material, the thickness of the ferroelectric material film may vary depending on the ferroelectric material.

As an example, the gate insulating film 130 may include one ferroelectric material film. As another example, the gate insulating film 130 may each include a plurality of ferroelectric material films spaced apart from each other. The gate insulating film 130 may have a stacked film structure in which the plurality of ferroelectric material films and the plurality of paraelectric material films are alternately stacked on each other.

A plurality of gate capping films 145 may each be placed on upper surfaces of the plurality of gate electrodes 120 and upper surfaces of the plurality of gate spacers 140. The plurality of gate capping films 145 may include, for example, at least one of silicon nitride (SiN), silicon oxynitride (SiON), silicon oxide (SiO₂), silicon carbonitride (SiCN), silicon oxycarbonitride (SiOCN), and combinations thereof.

A first source/drain pattern 150 may be placed on the substrate 100. The first source/drain pattern 150 may be formed on the first active pattern AP1. The first source/drain pattern 150 is connected to the first active pattern AP1. A bottom surface of the first source/drain pattern 150 is brought into contact with the first active pattern AP1.

The first source/drain pattern 150 may be placed at side surfaces of each of the plurality of gate electrodes 120. The first source/drain pattern 150 may be placed between the plurality of gate electrodes 120.

For example, the first source/drain patterns 150 may be placed on both sides of the plurality of gate electrodes 120. In addition, the first source/drain pattern 150 may be placed on one side of the plurality of gate electrodes 120 and might not be placed on the other side of the plurality of gate electrodes 120.

The first source/drain patterns 150 may include, for example, an epitaxial pattern. The first source/drain pattern 150 may include a semiconductor material. The first source/drain pattern 150 may be included in a source/drain of a transistor that uses the first active pattern AP1 as a channel region.

The first source/drain pattern 150 may be connected to a channel region that is used as a channel in the first active pattern AP1. Although the first source/drain pattern 150 is shown in a state in which three epitaxial patterns, which are formed on each first active pattern AP1, are merged, this is an example, and the present inventive concept is not limited thereto. For example, the epitaxial patterns formed on each first active pattern AP1 may be separated from each other.

As an example, an air gap may be placed in a space between the first source/drain patterns 150 merged with the field insulating film 105. As another example, the space between the first source/drain patterns 150 merged with the field insulating film 105 may be filled with an insulating material.

A second source/drain pattern 250 may be located on the substrate 100. The second source/drain pattern 250 may be formed on the second active pattern AP2. The second source/drain pattern 250 is connected to the second active pattern AP2. A bottom surface of the second source/drain pattern 250 is brought into contact with the second active pattern AP2.

The second source/drain patterns 250 may include, for example, an epitaxial pattern. The second source/drain pattern 250 may include a semiconductor material. The second source/drain pattern 250 may be included in the source/drain of a transistor that uses the second active pattern AP2 as a channel region.

The second source/drain pattern 250 may be connected to a channel region used as a channel in the second active pattern AP2. Although the second source/drain pattern 250 is shown in a state in which three epitaxial patterns, which are formed on each second active pattern AP2, are merged, this is an example, and the present inventive concept is not limited thereto. For example, the epitaxial patterns formed on each second active pattern AP2 may be separated from each other.

As an example, an air gap may be placed in a space between the second source/drain patterns 250 merged with the field insulating film 105. As another example, the space between the second source/drain patterns 250 merged with the field insulating film 105 may be filled with an insulating material.

A third source/drain pattern 350 may be located on the substrate 100. The third source/drain pattern 350 may be formed on the third active pattern AP3. The third source/drain pattern 350 is connected to the third active pattern AP3. A bottom surface of the third source/drain pattern 350 is brought into contact with the third active pattern AP3.

The third source/drain pattern 350 may include an epitaxial pattern. The third source/drain pattern 350 may include a semiconductor material. The third source/drain pattern 350 may be included in the source/drain of a transistor that uses the third active pattern AP3 as a channel region.

The third source/drain pattern 350 may be connected to a channel region used as a channel in the third active pattern AP3. Although the third source/drain pattern 350 is shown in a state in which three epitaxial patterns, which are formed on each third active pattern AP3, are merged, this is an example, and the present inventive concept is not limited thereto. For example, the epitaxial patterns formed on each third active pattern AP3 may be separated from each other.

As an example, an air gap may be placed in the space between the third source/drain patterns 350 merged with the field insulating film 105. As another example, the space between the third source/drain patterns 350 merged with the field insulating film 105 may be filled with an insulating material.

An etching stop film 160 may extend along the upper surface of the field insulating film 105, side walls of the plurality of gate spacers 140, the profile of the first source/drain pattern 150, the profile of the second source/drain pattern 250, and the profile of the third source/drain patterns 350. The etching stop film 160 may be placed on upper surfaces of the first to third source/drain patterns 150, 250 and 350, side walls of the first to third source/drain patterns 150, 250 and 350, and side walls of the plurality of gate spacers 140. In some embodiments of the present inventive concept, the etching stop film 160 is not placed on the side walls of the gate capping film 145. For example, the gate capping film 145 may be placed on the upper surface of the etching stop film 160. For example, the side walls of the etching stop film 160 may be connected to outer walls of the gate capping film 145. The etching stop film 160 may be placed on a side wall of the gate capping film 145.

The etching stop film 160 may include a material having an etching selectivity ratio with respect to the first interlayer insulating film 190, which will be described below. The etching stop film 160 may include a nitride-based insulating material. For example, it may include, for example, at least one of, for example, silicon nitride (SiN), silicon oxynitride (SiON), silicon oxycarbonitride (SiOCN), silicon boronitride (SiBN), silicon oxyboronitride (SiOBN), and combinations thereof.

A first interlayer insulating film 190 is placed on the etching stop film 160. The first interlayer insulating film 190 may be formed on the field insulating film 105. The first interlayer insulating film 190 may be placed on the first source/drain pattern 150, the second source/drain pattern 250 and the third source/drain pattern 350. The first interlayer insulating film 190 might not cover the upper surface of the gate capping film 145. For example, the upper surface of the first interlayer insulating film 190 may be placed on substantially the same plane as the upper surface of the gate capping film 145.

The first interlayer insulating film 190 may include, for example, but is not limited to, at least one of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

The first source/drain contact 170 may be placed on the first source/drain pattern 150. A second source/drain contact 270 may be placed on the second source/drain pattern 250. A third source/drain contact 370 may be placed on the third source/drain pattern 350.

A gate contact 180 may be connected to some of the plurality of gate electrodes 120. The gate contact 180 may be placed at a position which overlaps the plurality of gate electrodes 120.

The first source/drain contacts 170 penetrates the etching stop film 160, and may be connected to the first source/drain patterns 150. The first source/drain contact 170 may be placed on the first source/drain pattern 150.

The first source/drain contact 170 may be placed in the first interlayer insulating film 190. The first source/drain contacts 170 may be at least partially surrounded by the first interlayer insulating film 190.

A first contact silicide film 155 may be placed between the first source/drain contact 170 and the first source/drain pattern 150. Although the first contact silicide film 155 is shown as being formed along a profile of an interface between the first source/drain pattern 150 and the first source/drain contact 170, the present inventive concept is not limited thereto. The first contact silicide film 155 may include, for example, a metal silicide material.

The first interlayer insulating film 190 does not cover the upper surface of the first source/drain contact 170. As an example, the upper surface of the first source/drain contact 170 might not protrude above the upper surface of the first gate capping film 145. For example, an upper surface of the first interlayer insulating film 190 and the upper surface of the first source/drain contact 170 may be substantially coplanar. An upper surface of the first source/drain contact 170 may be placed on substantially the same plane as an upper surface of the gate capping film 145. As another example, the upper surface of the first source/drain contact 170 may protrude above the upper surface of the gate capping film 145.

In addition, the upper surface of the first source/drain contact 170 may be placed on substantially the same plane as the upper surface of the second source/drain contact 270 and the upper surface of the third source/drain contact 370. The upper surface of the first source/drain contact 170 may be placed on substantially the same plane as the upper surface of the gate contact 180. The upper surface of the first source/drain contact 170 may be placed on substantially the same plane as an upper surface of the power rail via PRVA.

In some embodiments of the present inventive concept, the first source/drain contact 170 may include a first source/drain barrier film 170BL, and a first source/drain filling film 170FL disposed on the first source/drain barrier film 170BL.

Although the bottom surface of the first source/drain contact 170 is shown to have a wavy shape or an uneven surface, the present inventive concept is not limited thereto. For example, the bottom surface of the first source/drain contact 170 may have a flat shape.

The first source/drain barrier film 170BL may include, for example, but is not limited to, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and/or a two-dimensional (2D) material. In the semiconductor device according to some embodiments of the present inventive concept, the two-dimensional material may be a metallic material and/or a semiconductor material. For example, the 2D material may include a 2D allotrope or a 2D compound, and may include, but is not limited to, at least one of graphene, molybdenum disulfide (MoS₂), molybdenum diselenide (MoSe₂), tungsten diselenide (WSe₂), and tungsten disulfide (WS₂). For example, since the above-mentioned 2D materials are only listed by way of example, the 2D materials that may be included in the semiconductor device according to an embodiment of the present inventive concept are not limited by the above-mentioned materials.

The first source/drain filling film 170FL may include, for example, at least one of aluminum (Al), tungsten (W), cobalt (Co), ruthenium (Ru), silver (Ag), gold (Au), manganese (Mn), and/or molybdenum (Mo).

Although the first source/drain contact 170 is shown as including plurality of conductive films, the present inventive concept is not limited thereto. Of course, the first source/drain contact 170 may be a single film.

The second source/drain contact 270 penetrates the etching stop film 160, and may be connected to the second source/drain pattern 250. The second source/drain contact 270 may be placed on the second source/drain pattern 250.

The second source/drain contact 270 may be placed inside the first interlayer insulating film 190. The second source/drain contacts 270 may be at least partially surrounded by the first interlayer insulating film 190.

A second contact silicide film 255 may be placed between the second source/drain contact 270 and the second source/drain pattern 250. Although the second contact silicide film 255 is shown as being formed along the profile of the interface between the second source/drain pattern 250 and the second source/drain contact 270, the present inventive concept is not limited thereto. The second contact silicide film 255 may include, for example, a metal silicide material.

The first interlayer insulating film 190 does not cover the upper surface of the second source/drain contact 270. For example, an upper surface of the first interlayer insulating film 190 and the upper surface of the second source/drain contact 270 may be substantially coplanar. As an example, the upper surface of the second source/drain contact 270 might not protrude above the upper surface of the gate capping film 145. The upper surface of the second source/drain contact 270 may be placed on substantially the same plane as the upper surface of the gate capping film 145. As another example, the upper surface of the second source/drain contact 270 may protrude above the upper surface of the gate capping film 145.

In addition, the upper surface of the second source/drain contact 270 may be placed on substantially the same plane as the upper side of the gate contact 180. The upper surface of the second source/drain contact 270 may be placed on substantially the same plane as the upper surface of the power rail via PRVA.

In some embodiments of the present inventive concept, the second source/drain contact 270 may include a second source/drain barrier film 270BL, and a second source/drain filling film 270FL disposed on the second source/drain barrier film 270BL. Contents of the materials included in the second source/drain barrier film 270BL and the second source/drain filling film 270FL may be the same as the description of the first source/drain barrier film 170BL and the second source/drain filling film 170FL.

Although the second source/drain contact 270 is shown to include a plurality of conductive films, the present inventive concept is not limited thereto. Of course, the second source/drain contact 270 may be a single film.

A third source/drain contact 370 penetrates the etching stop film 160, and may be connected to the third source/drain pattern 350. The third source/drain contact 370 may be placed on the third source/drain pattern 350.

The third source/drain contact 370 may be placed in the first interlayer insulating film 190. The third source/drain contacts 370 may be at least partially surrounded by the first interlayer insulating film 190.

A third contact silicide film 355 may be placed between the third source/drain contact 370 and the third source/drain pattern 350. Although the third contact silicide film 355 is shown as being formed along the profile of the interface between the third source/drain pattern 350 and the third source/drain contact 370, the present inventive concept is not limited thereto. The third contact silicide film 355 may include, for example, a metal silicide material.

The first interlayer insulating film 190 does not cover the upper surface of the third source/drain contact 370. For example, an upper surface of the first interlayer insulating film 190 and the upper surface of the third source/drain contact 370 may be substantially coplanar. As an example, the upper surface of the third source/drain contact 370 might not protrude above the upper surface of the gate capping film 145. The upper surface of the third source/drain contact 370 may be placed on substantially the same plane as the upper surface of the gate capping film 145. As another example, the upper surface of the third source/drain contact 370 may protrude above the upper surface of the gate capping film 145.

In addition, the upper surface of the third source/drain contact 370 may be placed on substantially the same plane as the upper surface of the gate contact 180. The upper surface of the third source/drain contact 370 may be placed on substantially the same plane as the upper surface of the power rail via PRVA.

In some embodiments of the present inventive concept, the third source/drain contact 370 may include a third source/drain barrier film 370BL, and a third source/drain filling film 370FL disposed on the third source/drain barrier film 370BL. Contents of the materials included in the third source/drain barrier film 370BL and the third source/drain filling film 370FL may be the same as the description of the first source/drain barrier film 170BL and the second source/drain filling film 170FL.

Although the third source/drain contact 370 is shown to include a plurality of conductive films, the present inventive concept is not limited thereto. The third source/drain contact 370 may, of course, be a single film.

The gate contact 180 may be placed on the gate electrode 120. The gate contact 180 penetrates the gate capping film 145, and may be connected to the gate electrode 120.

As an example, the upper surface of the gate contact 180 may be placed on substantially the same plane as the upper surface of the gate capping film 145. As another example, the upper surface of the gate contact 180 may protrude above the upper surface of the gate capping film 145.

The gate contact 180 may include a gate barrier film 180BL, and a gate filling film 180FL disposed on the gate barrier film 180BL. Contents of the materials included in the gate barrier film 180BL and the gate filling film 180FL may be the same as those described of the first source/drain barrier film 170BL and the first source/drain filling film 170FL.

The semiconductor device according to some embodiments of the present inventive concept may further include a lower insulating film 101, first to third semiconductor etching stop patterns 111, 112 and 113, and first to fourth semiconductor patterns 116, 117, 118 and 119.

The lower insulating film 101 may be placed on the lower side 100b of the substrate 100. The lower insulating film 101 may be brought into contact with the lower side 100b of the substrate 100.

The lower insulating film 101 may include, for example, at least one of silicon oxide, silicon nitride, silicon oxynitride, and/or a low dielectric constant material. The low dielectric constant material may include, for example, but is not limited to, at least one of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

A first semiconductor etching stop pattern 111 may be placed between the second active pattern AP2 and the third active pattern AP3. The first semiconductor etching stop pattern 111 may be placed inside the substrate 100. The first semiconductor etching stop pattern 111 may protrude from the upper side 100a of the substrate 100 in the third direction Z. For example, a height H2 of an upper surface 111U of the first semiconductor etching stop pattern 111 based on the lower side 100b of the substrate 100 may be greater than a height of the upper side 100a of the substrate based on the lower side 100b of the substrate 100. In addition, a height H2 of the upper surface 111 US of the first semiconductor etching stop pattern 111 based on the lower side 100b of the substrate 100 may be the same as the height H1 of the upper surface PR_US of the power rail PR based on the lower side 100b of the substrate.

A bottom surface 111BS of the first semiconductor etching stop pattern 1l1 may be placed on substantially the same plane as the lower side 100b of the substrate 100. The bottom surface 111BS of the first semiconductor etching stop pattern 111 may be brought into contact with the lower insulating film 101. A thickness of the first semiconductor etching stop pattern 111 in the third direction Z may be greater than a thickness of the substrate 100 in the third direction Z. In other words, the first semiconductor etching stop pattern 111 may overlap the substrate 100 in the first direction X and/or the second direction Y. For example, the first semiconductor etching stop pattern 111 may completely overlap the substrate 100 in the first direction X and/or the second direction Y. At least a part of the first semiconductor etching stop pattern 111 may be placed inside the field insulating film 105. At least a part of the first semiconductor etching stop pattern 111 may overlap the field insulating film 105 in the first direction X and/or the second direction Y.

In some embodiments of the present inventive concept, the upper surface 111US of the first semiconductor etching stop pattern 111 may be placed on substantially the same plane as the upper surface PR_US of the power rail PR, the upper surface 112US of a second semiconductor etching stop pattern 112, and the upper surface 113US of the third semiconductor etching stop pattern 113, which will be described below. In addition, a thickness of the first semiconductor etching stop pattern 111 in the third direction Z may be substantially the same as each of a thickness of the second semiconductor etching stop pattern 112 in the third direction Z and a thickness of the third semiconductor etching stop pattern 112 in the third direction Z.

The first semiconductor etching stop pattern 111 may include a material having an etching selectivity ratio with respect to the substrate 100. For example, if the substrate 100 is formed of silicon (Si), the first semiconductor etching stop pattern 111 may be formed of silicon-germanium (SiGe). The first semiconductor etching stop pattern 111 may be an epitaxial film that is grown from the substrate 100.

A first semiconductor pattern 116 may be placed on the first semiconductor etching stop pattern 111. At least a part of the first semiconductor pattern 116 may be placed inside the field insulating film 105. For example, at least a part of the first semiconductor pattern 116 may overlap the field insulating film 105 along the first direction X and/or the second direction Y. Although the first semiconductor pattern 116 is shown to overlap the field insulating film 105 along the second direction Y in FIG. 2, the present inventive concept is not limited thereto.

The first semiconductor pattern 116 may be formed of a material different from that of the first semiconductor etching stop pattern 111. For example, if the first semiconductor etching stop pattern 111 is formed of silicon-germanium (SiGe), the first semiconductor pattern 116 may be formed of silicon (Si). However, the present inventive concept is not limited thereto.

The second semiconductor etching stop pattern 112 may be placed on one side of the third active pattern AP3. For example, the second semiconductor etching stop pattern 112 may be placed on a side wall of the third active pattern AP3 that is opposite to the second active pattern AP2. The second semiconductor etching stop pattern 112 may be placed between the third active pattern AP3 and another active pattern. The second semiconductor etching stop pattern 112 may be placed in the substrate 100. The second semiconductor etching stop pattern 112 may protrude from the upper side 100a of the substrate 100 in the third direction Z. A bottom surface 112BS of the second semiconductor etching stop pattern 112 may be placed on substantially the same plane as the lower side 100b of the substrate 100. In addition, the bottom surface 112B of the second semiconductor etching stop pattern 112 may be brought into contact with the lower insulating film 101.

The second semiconductor etching stop pattern 112 may include a material having an etching selectivity ratio with respect to the substrate 100. For example, if the substrate 100 is formed of silicon (Si), the second semiconductor etching stop pattern 112 may be formed of silicon-germanium (SiGe). The second semiconductor etching stop pattern 112 may be an epitaxial film that is grown from the substrate 100.

A second semiconductor pattern 117 may be placed on the second semiconductor etching stop pattern 112. At least a part of the second semiconductor pattern 117 may be placed inside the field insulating film 105. At least a part of the second semiconductor pattern 117 may overlap the field insulating film 105 along the first direction X and/or the second direction Y.

The second semiconductor pattern 117 may be formed of a material different from that of the second semiconductor etching stop pattern 112. For example, if the second semiconductor etching stop pattern 112 is formed of silicon-germanium (SiGe), the second semiconductor pattern 117 may be formed of silicon (Si). However, the technical idea of the present disclosure is not limited thereto.

The third semiconductor etching stop pattern 113 may be placed on one side of the first active pattern AP1. For example, the third semiconductor etching stop pattern 113 may be placed on a side wall of the first active pattern AP1 that is opposite to the second active pattern AP2. The third semiconductor etching stop pattern 113 may be placed between the first active pattern AP1 and another active pattern. The third semiconductor etching stop pattern 113 may be placed in the substrate 100. The third semiconductor etching stop pattern 113 may protrude from the upper side 100a of the substrate 100 in the third direction Z. A bottom surface 113BS of the third semiconductor etching stop pattern 113 may be placed on the same plane as the lower side 100b of the substrate 100. In addition, the bottom surface 113BS of the third semiconductor etching stop pattern 113 may be brought into contact with the lower insulating film 101.

The third semiconductor etching stop pattern 113 may include a material having an etching selectivity ratio with respect to the substrate 100. For example, if the substrate 100 is formed of silicon (Si), the third semiconductor etching stop pattern 113 may be formed of silicon-germanium (SiGe). The third semiconductor etching stop pattern 113 may be, for example, an epitaxial film that is grown from the substrate 100.

A third semiconductor pattern 118 may be placed on the third semiconductor etching stop pattern 113. At least a part of the third semiconductor pattern 118 may be placed inside the field insulating film 105. At least a part of the third semiconductor pattern 118 may overlap the field insulating film 105 along the first direction X and/or the second direction Y.

The third semiconductor pattern 118 may be formed of a material different from that of the third semiconductor etching stop pattern 113. For example, if the third semiconductor etching stop pattern 113 is formed of silicon-germanium (SiGe), the third semiconductor pattern 118 may be formed of silicon (Si). However, the present inventive concept is not limited thereto.

Unlike the shown example, some of the first to third semiconductor etching stop patterns 111, 112, and 113 might not be formed.

The power rail PR may be placed between the first active pattern AP 1 and the second active pattern AP2. The power rail PR might not be placed between the second active pattern AP2 and the third active pattern AP3. This may be because a first spaced distance d1 in the second direction Y between the first active pattern AP1 and the second active pattern AP2 is greater than a second spaced distance d2 in the second direction Y between the second active pattern AP2 and the third active pattern AP3. The power rail PR may extend lengthwise in the first direction X, but the present inventive concept is not limited thereto.

In some embodiments of the present inventive concept, the power rail PR may include a power line PR1 and a via PR2. The power line PR1 may extend long in the first direction X. The via PR2 may be a portion connected to a power rail via PRVA, which will be described below.

The power line PR1 is placed on the lower side 100b of the substrate 100. The power line PR1 is placed in the lower insulating film 101. The via PR2 is placed on the power line PR1. At least a part of the via PR2 is placed inside the substrate 100. The via PR2 might not overlap the lower insulating film 101 along the first direction X and/or the second direction Y, but present inventive concept is not limited thereto.

In some embodiments of the present inventive concept, a height of the via PR2 may be the same as a height of the first semiconductor etching stop pattern 111. For example, the upper surface of the via PR2, for example, the upper surface PR_US of the power rail PR and the upper surface 11lUS of the first semiconductor etching stop pattern 111 may be placed on substantially the same plane.

In some embodiments of the present inventive concept, the power rail PR may be connected with the first source/drain pattern 150. For example, the power rail PR may be connected to the first source/drain pattern 150 through the power rail via PRVA, the via plug 195 and the first source/drain contact 170. A voltage may be applied to the first source/drain pattern 150 through the power rail PR.

The power rail PR may include, for example, at least one of a metal, a metal alloy, a conductive metal nitride, a conductive metal carbide, a conductive metal oxide, a conductive metal carbonitride, and/or a two-dimensional (2D) material.

In some embodiments of the present inventive concept, a fourth semiconductor pattern 119 may be placed on the power rail PR. For example, the fourth semiconductor pattern 119 is placed on the upper surface PR_US of the power rail PR. At least a part of the fourth semiconductor pattern 119 may be placed in the field insulating film 105. At least a part of the fourth semiconductor pattern 119 may overlap the field insulating film 105 along the first direction X and/or the second direction Y.

The fourth semiconductor pattern 119 may be formed through the same process as the first to third semiconductor patterns 116, 117 and 118. Therefore, the thickness of the fourth semiconductor pattern 119 is substantially the same as the thicknesses of the first to third semiconductor patterns 116, 117 and 118. The fourth semiconductor pattern 119 may be formed of, for example, silicon (Si). However, the present inventive concept is not limited thereto.

The power rail via PRVA may be placed on the power rail PR. The power rail via PRVA may be connected to the power rail PR. The power rail via PRVA may be placed between the plurality of gate electrodes 120. In addition, the power rail via PRVA may be placed between the first active pattern AP1 and the second active pattern AP2. For example, the power rail via PRVA may be placed between the first source/drain pattern 150 and the second source/drain pattern 250. The power rail via PRVA may be placed between the first source/drain contact 170 and the second source/drain contact 270.

The power rail via PRVA penetrates the first interlayer insulating film 190, the etching stop film 160, and the fourth semiconductor pattern 119, and may be connected to the power rail PR. The lower surface of the power rail via PRVA may be brought into contact with the upper surface PR_US of the power rail PR. In some embodiments of the present inventive concept, although the height of the upper surface 111US of the first semiconductor etching stop pattern 111 based on the lower side 100b of the substrate 100 may be substantially the same as the height of the lower surface of the power rail via PRVA based on the lower side 100b of the substrate 100, the present inventive concept is not limited thereto.

The first interlayer insulating film 190 might not cover the upper surface of the power rail via PRVA. For example, the upper surface of the power rail via PRVA may be placed on substantially the same plane as the upper surface of the first interlayer insulating film 190. In addition, the upper surface of the power rail via PRVA may be placed on substantially the same plane as the upper surface of the first source/drain contact 170, the upper surface of the second source/drain contact 270, and the upper surface of the third source/drain contact 370. In addition, the upper surface of the power rail via PRVA may be placed on substantially the same plane as the upper surface of the gate contact 180 and the upper surface of the gate capping film 145.

In some embodiments of the present inventive concept, the power rail via PRVA may include a power rail via barrier film PRVA BL, and a power rail via filling film PRVA_FL disposed on the power rail via barrier film PRVA BL. The contents of the materials included in the power rail via barrier film PRVA BL and the power rail via filling film PRVA_FL may be the same as the description of the first source/drain barrier film 170BL and the second source/drain filling film 170FL.

An upper stop film 191 may be placed on the first interlayer insulating film 190, the gate capping film 145, the first source/drain contact 170, the second source/drain contact 270, the third source/drain contact 370, the power rail via PRVA and the gate contact 180. A second interlayer insulating film 192 is placed on the upper stop film 191.

The upper stop film 191 may include a material having an etching selectivity ratio with respect to the second interlayer insulating film 192. The upper stop film 191 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), aluminum oxide (AlO), aluminum nitride (AlN), aluminum oxycarbide (AlOC), and combinations thereof. Although the upper stop film 191 is shown as being a single film, the present inventive concept is not limited thereto. For example, the upper stop film 191 might not be formed. The second interlayer insulating film 192 may include, for example, at least one of silicon oxide, silicon nitride, silicon carbonitride, silicon oxynitride, and a low dielectric constant material.

The via plug 195 may be placed in the second interlayer insulating film 192. The via plug 195 passes through the upper stop film 191, and may be connected to the first source/drain contact 170, the power rail via PRVA, the second source/drain contact 270, the third source/drain contact 370, and the gate contact 180. For example, the via plug 195 may be directly connected to the first source/drain contact 170, the power rail via PRVA, the second source/drain contact 270, the third source/drain contact 370, and the gate contact 180.

A part of the via plug 195 may cover the upper surface of the first source/drain contact 170 and the upper surface of the power rail via PRVA. For example, the via plug 195 may completely cover the upper surface of the first source/drain contact 170 and the upper surface of the power rail via PRVA. For example, the first source/drain contact 170 and the power rail via PRVA may be connected to the single via plug 195.

The via plug 195 may include a via barrier film 195BL and a via filling film 195FL. The via barrier film 195BL may extend along the side walls and a bottom surface of the via filling film 195BL. The via barrier film 195BL may include, for example, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and/or a two-dimensional (2D) material. The wiring filling film 195BL may include, for example, at least one of aluminum (Al), tungsten (W), cobalt (Co), ruthenium (Ru), copper (Cu), silver (Ag), gold (Au), manganese (Mn), and/or molybdenum (Mo).

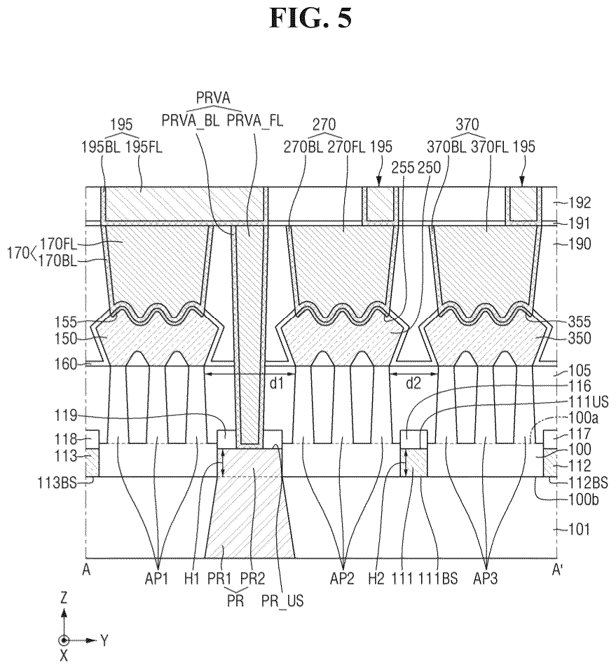

A semiconductor device according to some embodiments of the present inventive concept will be described below with reference to FIGS. 5 to 14. For convenience of explanation, points that are different from those explained using FIGS. 1 to 4 will be mainly explained, and redundant descriptions may be omitted or briefly discussed.

FIGS. 5 to 10 are diagrams illustrating a semiconductor device according to some embodiments of the present inventive concept.

First, referring to FIG. 5, a thickness of the first semiconductor etching stop pattern 111 in the third direction Z may be smaller than a thickness of the substrate 100 in the third direction Z. For example, the height H2 of the upper surface 111 US of the first semiconductor etching stop pattern 111 based on the bottom surface 111BS of the first semiconductor etching stop pattern Ill is smaller than the height of the upper side 100a of the substrate 100 based on the lower side 100b of the substrate 100. For example, the first semiconductor etching stop pattern 111 may completely overlap the substrate 100 along the first direction X and/or the second direction Y.

Similarly, each of the thicknesses of the second and third semiconductor etching stop patterns 112 and 113 in the third direction Z may be smaller than the thickness of the substrate 100 in the third direction Z. The height of the upper surface of the second semiconductor etching stop pattern 112 based on the lower side 100b of the substrate 100 is smaller than the height of the upper side 100a of the substrate 100 based on the lower side 100b of the substrate 100. In addition, the height of the upper surface of the third semiconductor pattern 113 based on the lower side 100b of the substrate 100 is smaller than the height of the upper side 100a of the substrate 100 based on the lower side 100b of the substrate 100. For example, each of the second and third semiconductor etching stop patterns 112 and 113 may overlap the substrate 100 along the first direction X and/or the second direction Y.

In some embodiments of the present inventive concept, the thickness of the via PR2 of the power rail PR may be smaller than the thickness of the substrate 100. A height H1 of the upper surface of the via PR2 of the power rail PR based on the lower side 100b of the substrate 100 may be smaller than the height of the upper side 100a of the substrate 100 based on the lower side 100b of the substrate 100. For example, the via PR2 of the power rail PR may overlap the substrate 100 along the first direction X and/or the second direction Y.

In some embodiments of the present inventive concept, at least a part of the first to fourth semiconductor patterns 116, 117, 118, and 119 may be placed in the substrate 100.

A part of each of the first to fourth semiconductor patterns 116, 117, 118 and 119 may be placed in the field insulating film 105, and another part of each of the first to fourth semiconductor patterns 116, 117, 118 and 119 may be placed in the substrate 100. For example, at least a part of the first to fourth semiconductor patterns 116, 117, 118, and 119 may overlap the substrate 100 along the first direction X and/or the second direction Y.

In some embodiments of the present inventive concept, although at least a part of the power rail via PRVA may overlap the substrate 100 in the first direction X and/or the second direction Y, the present inventive concept is not limited thereto.

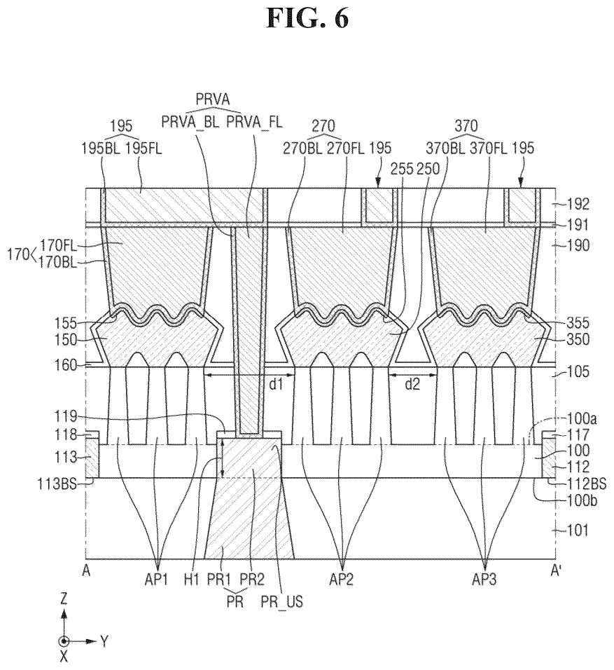

Referring to FIG. 6, the first semiconductor etching stop pattern 111 and the first semiconductor pattern 116 might not be formed. For example, the semiconductor etching stop pattern might not be formed between the active patterns. In this case, the level of the lower side 100b of the substrate 100 between the second active pattern AP2 and the third active pattern AP3 may be higher than the level of the bottom surface 112BS of the second semiconductor etching stop pattern 112. This may be because the substrate 100 is over-etched as the first semiconductor etching stop pattern 111 is not formed. However, the present inventive concept is not limited thereto.

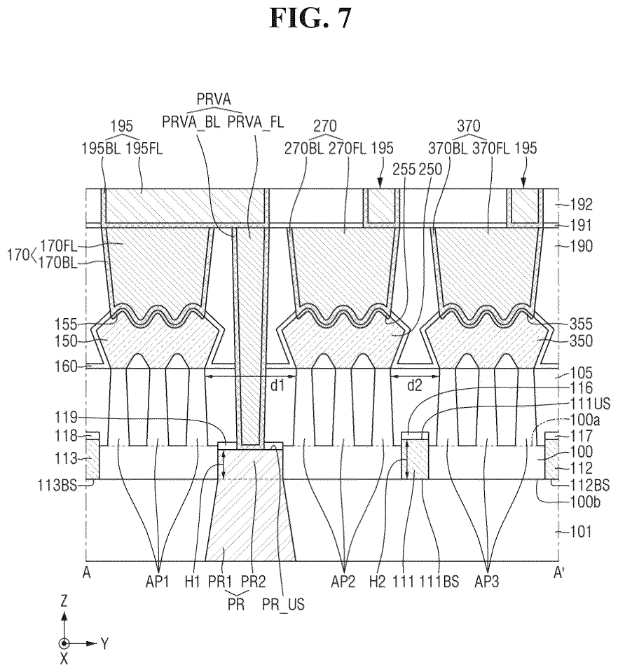

Referring to FIG. 7, the thickness of the first semiconductor etching stop pattern 111 and the thickness of the via PR2 of the power rail PR may be different from each other.

For example, the thickness of the first semiconductor etching stop pattern 111 in the third direction Z may be greater than the thickness of the via PR2 of the power rail PR in the third direction Z. For example, the height H1 of the upper surface PR_US of the power rail PR based on the lower side 100b of the substrate 100 is smaller than the height H2 of the upper surface 111US of the first semiconductor etching stop pattern Ill based on the lower side 100b of the substrate 100. This may be because the first spaced distance d1 in the second direction Y between the first active pattern AP1 and the second active pattern AP2 is greater than the second spaced distance d2 in the second directions Y between the second active pattern AP2 and the third active pattern AP3.

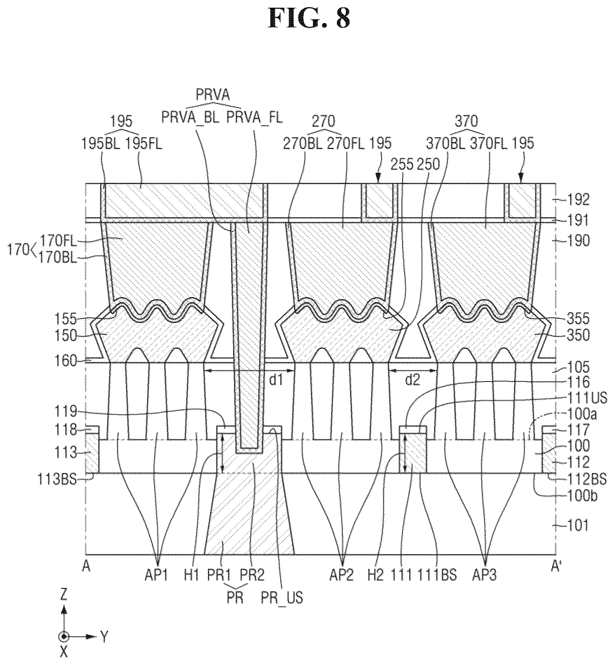

Referring to FIG. 8, at least a part of the power rail via PRVA may be placed inside the power rail PR. In addition, the height of the lower surface of the power rail via PRVA based on the lower side 100b of the substrate 100 may be smaller than the height of the upper surface PR_US of the power rail PR based on the lower side 100b of the substrate 100. Similarly, the height of the lower surface of the power rail via PRVA based on the lower side 100b of the substrate 100 may be smaller than the height of the upper surface 111US of the first semiconductor etching stop pattern 111 based on the lower side 100b of the substrate 100.

Moreover, at least a part of the power rail via PRVA may overlap the power rail PR along the first direction X and/or the second direction Y. For example, the power rail via PRVA may overlap the power rail PR in third direction Z. At least a part of the power rail via PRVA may overlap the first semiconductor etching stop pattern 111, the second semiconductor etching stop pattern 112 and/or the third semiconductor etching stop pattern 113 in the first direction X and/or the second direction Y.

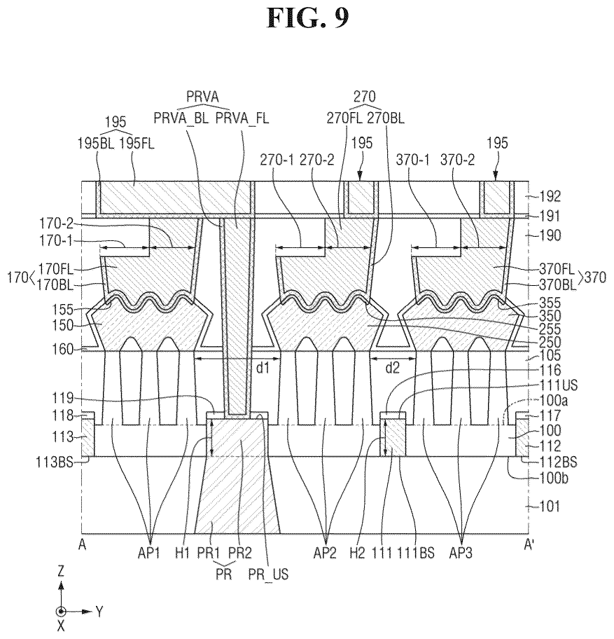

Referring to FIG. 9, in the semiconductor device according to some embodiments of the present inventive concept, a first source/drain contact 170 may include a first portion 170-1 and a second portion 170-2. The second source/drain contact 270 may include a first portion 270-1 and a second portion 270-2. The third source/drain contact 370 may include a first portion 370-1 and a second portion 370-2. Descriptions of the second source/drain contact 270 and the third source/drain contact 370 may be substantially the same as the description of the first source/drain contact 170, and thus the descriptions may be omitted or briefly discussed.

The first portion 170-1 of the first source/drain contact 170 may be connected to the second portion 170-2 of the first source/drain contact 170. For example, the first portion 170-1 of the first source/drain contact 170 may be directly connected to the second portion 170-2 of the first source/drain contact 170.

The second portion 170-2 of the first source/drain contact 170 is a portion on which the via plug 195 lands. The first source/drain contact 170 may be connected to the via plug 195 through the second portion 170-2 of the first source/drain contact 170. The first portion 170-1 of the first source/drain contact 170 is not a portion on which the via plug 195 lands.

For example, the second portion 170-2 of the first source/drain contact 170 may be located at the portion connected to the via plug 195. The first portion 170-1 of the first source/drain contact 170 may be located in a portion that is not connected to the via plug 195.

In addition, to prevent the gate contact 180 and the first source/drain contact 170 from being short-circuited, the first portion 170-1 of the first source/drain contact 170 may be located on both sides of the gate electrode 120 of the portion connected to the gate contact 180, and the second portion 170-2 of the first source/drain contact 170 might not be located on both sides of the gate electrode 120 of the portion connected to the gate contact 180.

The upper surface of the second portion 170-2 of the first source/drain contact 170 is higher than the upper surface of the first portion 170-1 of the first source/drain contact 170. The upper surface of the second portion 170-2 of the first source/drain contact 170 is higher than the upper surface of the first portion 170-1 of the first source/drain contact 170, on the basis of the upper side of the field insulating film 105. For example, the upper surface of the first source/drain contact 170 may be the upper surface of the second portion 170-2 of the first source/drain contact 170.

In FIG. 9, the first source/drain contact 170 is shown as having an L′ shape, but the present inventive concept is not limited thereto. For example, the first source/drain contact 170 may have a T-shape that is rotated by 180 degrees. In such a case, the first portion 170-1 of the first source/drain contact 170 may be placed on both sides of the second portion 170-2 of the first source/drain contact 170.

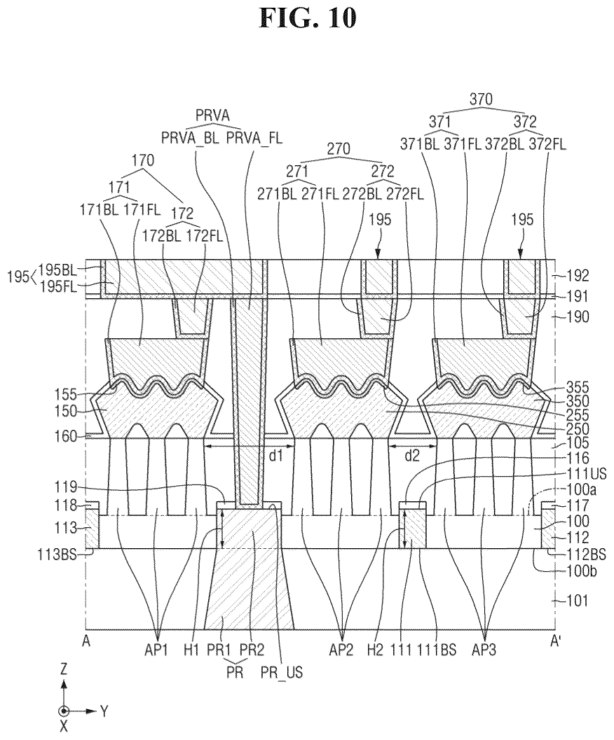

Referring to FIG. 10, in the semiconductor device according to some embodiments of the present inventive concept, the first source/drain contact 170 may include a first lower source/drain contact 171 and a first upper source/drain contact 172. The second source/drain contact 270 may include a second lower source/drain contact 271 and a second upper source/drain contact 272. The third source/drain contact 370 may include a third lower source/drain contact 371 and a third upper source/drain contact 372.

The first lower source/drain contact 171 may include a first lower source/drain barrier film 171BL and a first lower source/drain filling film 171FL. The first upper source/drain contact 172 may include a first upper source/drain barrier film 172BL and a first upper source/drain filling film 172FL.

The upper surface of the first source/drain contact 170 may be an upper surface of the first upper source/drain contact 172.

Contents of the materials included in the first lower source/drain barrier film 171BL and the first upper source/drain barrier film 172BL may be the same as the description of the first source/drain barrier film 170BL. Contents of the materials included in the first lower source/drain filling film 171FL and the first upper source/drain filling film 172FL may be the same as the description of the first source/drain filling film 170FL. For example, the first upper source/drain contact 172 may be formed of a single film.

The second lower source/drain contact 271 may include a second lower source/drain barrier film 271BL and a second lower source/drain filling film 271FL. The second upper source/drain contact 272 may include a second upper source/drain barrier film 272BL and a second upper source/drain filling film 272FL.

The upper surface of the second source/drain contact 270 may be an upper surface of the second upper source/drain contact 272.

Contents of the materials included in the second lower source/drain barrier film 271BL and the second upper source/drain barrier film 272BL may be the same as the description of the first source/drain barrier film 170BL. Contents of the materials included in the second lower source/drain filling film 271FL and the second upper source/drain filling film 272FL may be the same as the description of the first source/drain filling film 170FL. For example, the second upper source/drain contact 272 may be formed of a single film.

The third lower source/drain contact 371 may include a third lower source/drain barrier film 371BL and a third lower source/drain filling film 371FL. The third upper source/drain contact 372 may include a third upper source/drain barrier film 372BL and a third upper source/drain filling film 372FL.

The upper surface of the third source/drain contact 370 may be an upper surface of the third upper source/drain contact 372.

Contents of the materials included in the third lower source/drain barrier film 371BL and the third upper source/drain barrier film 372BL may be the same as the description of the first source/drain barrier film 170BL. Contents of the materials included in the third lower source/drain filling film 371FL and the third upper source/drain filling film 372FL may be the same as the description of the first source/drain filling film 170FL. For example, the third upper source/drain contact 372 may be formed of a single film.

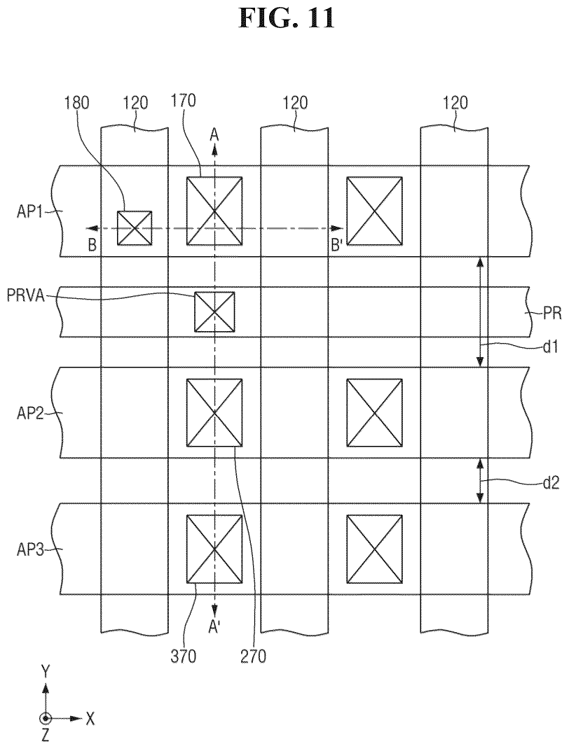

FIGS. 11 to 14 are diagrams illustrating a semiconductor device according to some embodiments of the present inventive concept.

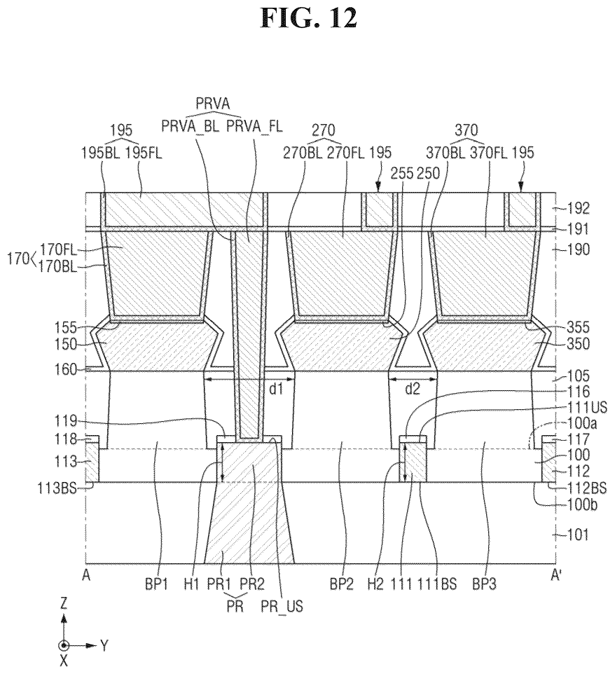

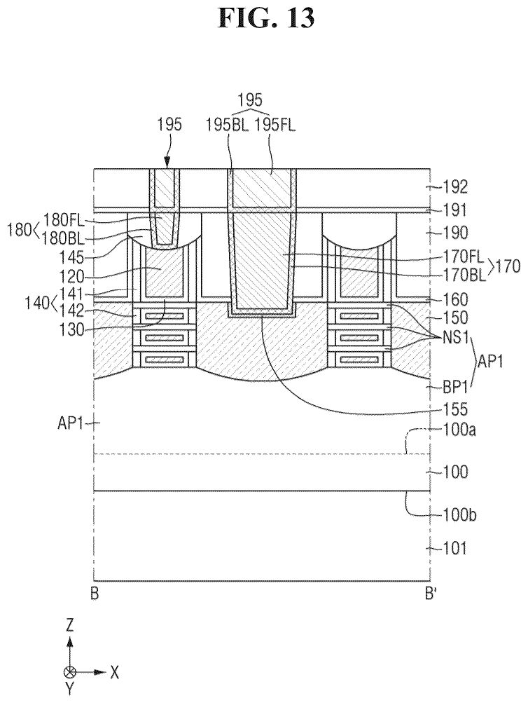

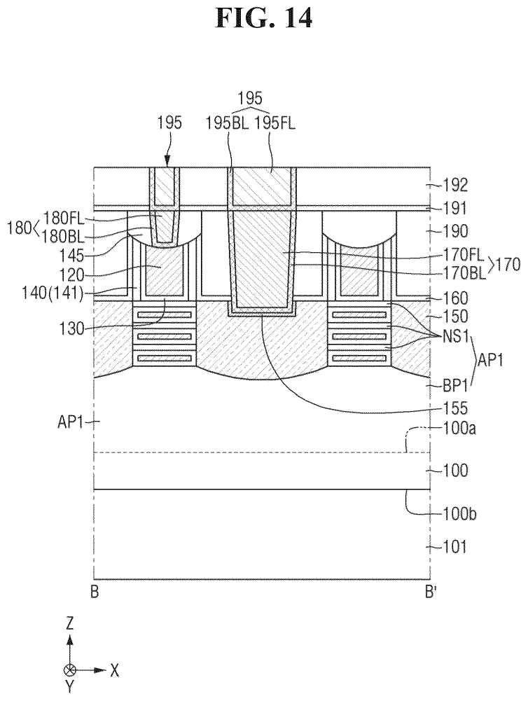

FIG. 11 is a layout diagram illustrating a semiconductor device according to some embodiments of the present inventive concept. FIGS. 12 and 13 are cross-sectional views taken along a line A-A′ of FIG. 11, respectively. FIG. 14 is a cross-sectional view taken along a line B-B′ of FIG. 11. For convenience of explanation, points that are different from those explained using FIGS. 1 to 4 will be mainly explained, and redundant descriptions may be omitted or briefly discussed.

Referring to FIGS. 11 to 14, in the semiconductor device according to some embodiments of the present inventive concept, a first active pattern AP1 may include a first lower pattern BP 1 and at least one or more first sheet patterns NS 1. The second active pattern AP2 may include a second lower pattern BP2 and at least one or more second sheet patterns. Similarly, the third active pattern AP3 may include a third lower pattern BP3 and at least one or more third sheet patterns.

The first lower pattern BP1 may extend along the first direction X. The first sheet pattern NS1 may be placed on the first lower pattern BP1 and may be spaced apart from the first lower pattern BP1. The second and third lower patterns BP2 and BP3 may extend along the first direction X. In some embodiments of the present inventive concept, the first spaced distance d1 in the second direction Y between the first lower pattern BP 1 and the second lower pattern BP2 may be greater than the second spaced distance d2 in the second direction Y between the second lower pattern BP2 and the third lower pattern BP3.

The first sheet pattern NS1 may include a plurality of sheet patterns stacked on each other in the third direction Z. For example, the second sheet pattern and the third sheet pattern may each include a plurality of sheet patterns stacked in the third direction Z. Although three first sheet patterns NS1 are shown, this is only for convenience of explanation, and the present inventive concept is not limited thereto. An upper surface of the first sheet pattern NS1 placed on the uppermost part among the first sheet patterns NS 1 may be an upper surface of the first active pattern AP 1.

The first sheet pattern NS1 may be connected to the first source/drain pattern 150. The first sheet pattern NS1 may be a channel pattern used as a channel region of a transistor. For example, the first sheet pattern NS1 may be a nanosheet or a nanowire. The second sheet pattern may be connected to the second source/drain pattern 250. The second sheet pattern may be a channel pattern used as a channel region of a transistor. For example, the second sheet pattern may be a nanosheet or a nanowire. The third sheet pattern may be connected to the third source/drain pattern 350. The third sheet pattern may be a channel pattern used as a channel region of a transistor. For example, the third sheet pattern may be a nanosheet or a nanowire.

The first to third lower patterns BP1, BP2, and BP3 may include, for example, silicon or germanium which is an elemental semiconductor material. In addition, the first to third lower patterns BP 1, BP2, and BP3 may include a compound semiconductor, and may include, for example, a group IV-IV compound semiconductor or a group III-V compound semiconductor.

The first sheet pattern NS1 may include, for example, silicon or germanium which is an elemental semiconductor material. In addition, the first sheet pattern NS1 may include a compound semiconductor, and may include, for example, a group IV-IV compound semiconductor or a group III-V compound semiconductor.

In FIG. 12, the power rail PR may be placed between the first lower pattern BP1 and the second lower pattern BP2.

The first source/drain pattern 150 may be placed on the first lower pattern BP 1. The first source/drain pattern 150 may be placed between the plurality of gate electrodes 120. The first source/drain pattern 150 may be connected to the first sheet pattern NS1. The second source/drain pattern 250 may be placed on the second lower pattern BP2. The second source/drain pattern 250 may be placed between the plurality of gate electrodes 120. The second source/drain pattern 250 may be connected to the second sheet pattern. A third source/drain pattern 350 may be placed on the third lower pattern BP3. The third source/drain pattern 350 may be placed between the plurality of gate electrodes 120. The third source/drain pattern 350 may be connected to the third sheet pattern.

The power rail via PRVA may be placed between the first lower pattern BP1 and the second lower pattern BP2. The power rail via PRVA is placed between the first source/drain pattern 150 and the second source/drain pattern 250. In addition, the power rail via PRVA may be placed between the plurality of gate electrodes 120.

The gate insulating film 130 may extend along the upper surfaces of the first to third lower patterns BP1, BP2, and BP3 and the upper surface of the field insulating film 105. The gate insulating film 130 may wrap around the first sheet pattern NS1, the second sheet pattern, and the third sheet pattern.

The gate electrode 120 is placed on the first to third lower patterns BP1, BP2 and BP3. The gate electrode 120 intersects the first to third lower patterns BP1, BP2 and BP3. The gate electrode 120 may wrap around the first sheet pattern NS 1, the second sheet pattern, and the third sheet pattern.

In FIG. 13, the gate spacer 140 may include an outer spacer 141 and an inner spacer 142. The inner spacer 142 may be placed between the first lower pattern BP1 and the first sheet pattern NS1, and between the adjacent first sheet pattern NS1.

In FIG. 14, the gate spacer 140 may include only the outer spacer 141. No inner spacer is placed between the first lower pattern BP1 and the first sheet pattern NS 1, and between the adjacent first sheet patterns NS1.

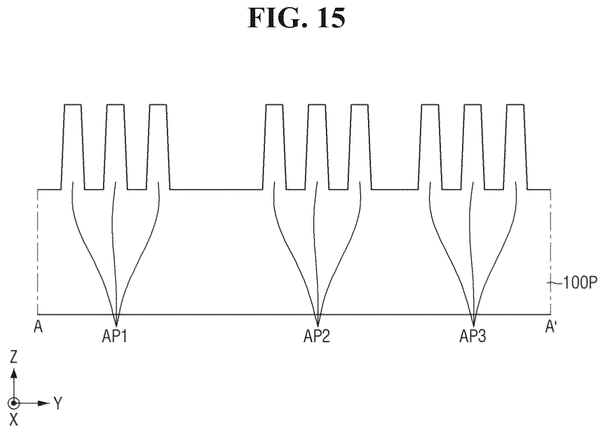

FIGS. 15 to 28 are intermediate step diagrams illustrating a method of manufacturing a semiconductor device according to some embodiments of the present inventive concept. For reference, FIGS. 15 to 28 may be cross-sectional views taken along a line A-A′ of FIG. 1. The following manufacturing method will be described in terms of cross-sectional views.

Referring to FIG. 15, a pre substrate 100P may be provided. The first active pattern AP1, the second active pattern AP2, and the third active pattern AP3 may be formed on the pre substrate 100P. The pre substrate 100P may be patterned to form the first active pattern AP1, the second active pattern AP2, and the third active pattern AP3. The pre substrate 100P may be, but is not limited to, a silicon substrate.

In some embodiments of the present inventive concept, the first spaced distance d1 in the second direction Y between the first active pattern AP1 and the second active pattern AP2 may be greater than the second spaced distance d2 in the second direction Y between the second active pattern AP2 and the third active pattern AP3, but the present inventive concept is not limited thereto.

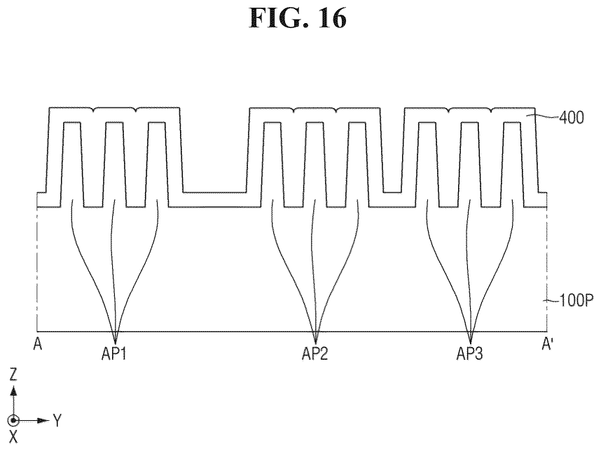

Referring to FIG. 16, a capping liner film 400 may be formed. The capping liner film 400 may be formed along the upper side of the pre substrate 100P, the profile of the first active pattern AP1, the profile of the second active pattern AP2, and the profile of the third active pattern AP3. The capping liner film 400 may be conformally formed on the pre substrate 100P, but the present inventive concept is not limited thereto.

The capping liner film 400 may include an insulating material. For example, capping liner film 400 may include an oxide film, a nitride film, an oxynitride film or a combination thereof.

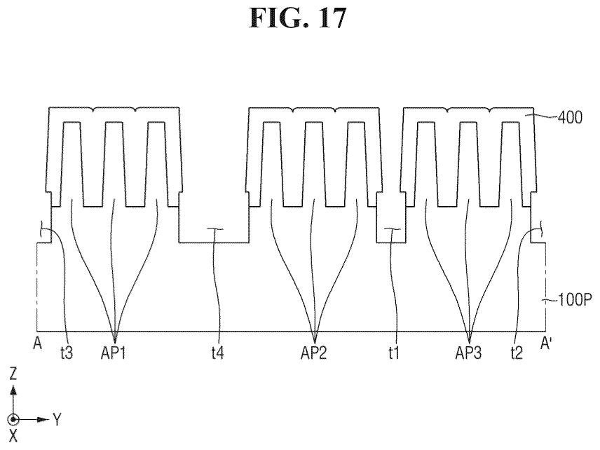

Referring to FIG. 17, a part of the capping liner film 400 and the pre substrate 100P may be etched to form first to fourth trenches t1, t2, t3 and t4.

A first trench t1 may be formed between the second active pattern AP2 and the third active pattern AP3. A second trench t2 may be formed on a side wall of the third active pattern AP3 that is opposite to another sidewall of the third active pattern AP3 that is facing the second active patterns AP2. A third trench t3 may be formed on a side wall of the first active pattern AP1 that is opposite to another sidewall of the first active pattern AP1 that is facing the second active pattern AP2. A fourth trench t4 may be formed between the first active pattern AP 1 and the second active pattern AP2.

The first to fourth trenches t1, t2, t3, and t4 may be formed through the same process. Therefore, all the bottom surfaces of the first to fourth trenches t1, t2, t3, and t4 may be placed on substantially the same plane. In some embodiments of the present inventive concept, the width of the fourth trench t4 may be greater than the width of the first trench t1. However, the present inventive concept is not limited thereto.

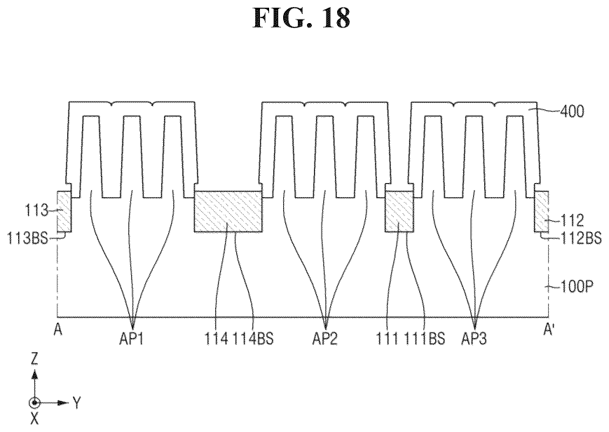

Referring to FIG. 18, a first semiconductor etching stop pattern 111, a second semiconductor etching stop pattern 112, a third semiconductor etching stop pattern 113, and a fourth semiconductor etching stop pattern 114 may be formed.

The first semiconductor etching stop pattern 111 may be formed in the first trench t1. The second semiconductor etching stop pattern 112 may be formed in the second trench Q. The third semiconductor etching stop pattern 113 may be formed in the third trench t3. The fourth semiconductor etching stop pattern 114 may be formed in the fourth trench t4.

Each of the first semiconductor etching stop pattern 111, the second semiconductor etching stop pattern 112, the third semiconductor etching stop pattern 113, and the fourth semiconductor etching stop pattern 114 may be an epitaxial film that is grown from the pre substrate 100P. Each of the first semiconductor etching stop pattern 111, the second semiconductor etching stop pattern 112, the third semiconductor etching stop pattern 113, and the fourth semiconductor etching stop pattern 114 may include a material having an etching selectivity ratio with respect to the pre substrate 100P. For example, the first semiconductor etching stop pattern 111, the second semiconductor etching stop pattern 112, the third semiconductor etching stop pattern 113, and the fourth semiconductor etching stop pattern 114 may each include, but is not limited to, silicon-germanium (SiGe).

In some embodiments of the present inventive concept, the bottom surface 111BS of the first semiconductor etching stop pattern 111, the bottom surface 112BS of the second semiconductor etching stop pattern 112, the bottom surface 113BS of the third semiconductor etching stop pattern 113, and the bottom surface 114BS of the fourth semiconductor etching stop pattern 114 may all be placed on substantially the same plane. In addition, the upper surface of the first semiconductor etching stop pattern 111, the upper surface of the second semiconductor etching stop pattern 112, the upper surface of the third semiconductor etching stop pattern 113, and the upper surface of the fourth semiconductor etching stop pattern 114 may all be placed on substantially the same plane.

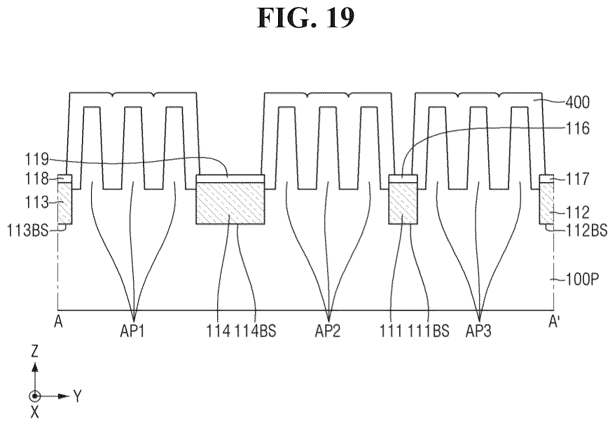

Referring to FIG. 19, a first semiconductor pattern 116, a second semiconductor pattern 117, a third semiconductor pattern 118, and a fourth semiconductor pattern 119 may be formed.

The first semiconductor pattern 116 is formed on the first semiconductor etching stop pattern 111. The second semiconductor pattern 117 is formed on the second semiconductor etching stop pattern 112. The third semiconductor pattern 118 is formed on the third semiconductor etching stop pattern 113. The fourth semiconductor pattern 119 is formed on the fourth semiconductor etching stop pattern 114. The first semiconductor pattern 116, the second semiconductor pattern 117, the third semiconductor pattern 118, and the fourth semiconductor pattern 119 may all have substantially the same thickness as one another.

Each of the first semiconductor pattern 116, the second semiconductor pattern 117, the third semiconductor pattern 118, and the fourth semiconductor pattern 119 may be formed of materials different from those of the first to fourth semiconductor etching stop patterns 111, 112, 113, and 114. For example, the first semiconductor pattern 116, the second semiconductor pattern 117, the third semiconductor pattern 118, and the fourth semiconductor pattern 119 may each be formed of silicon (Si).

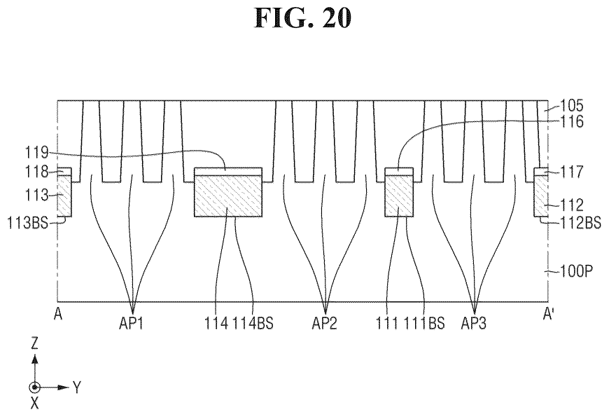

Referring to FIG. 20, the field insulating film 105 may be formed. The field insulating film 105 may be formed on the first to fourth semiconductor patterns 116, 117, 118 and 119. In addition, the field insulating film 105 may be formed on the side walls of the first active pattern AP1, the side walls of the second active pattern AP2, and the side walls of the third active pattern AP3. The material included in the field insulating film 105 may be the same as the material included in the capping liner film (400 of FIG. 16).

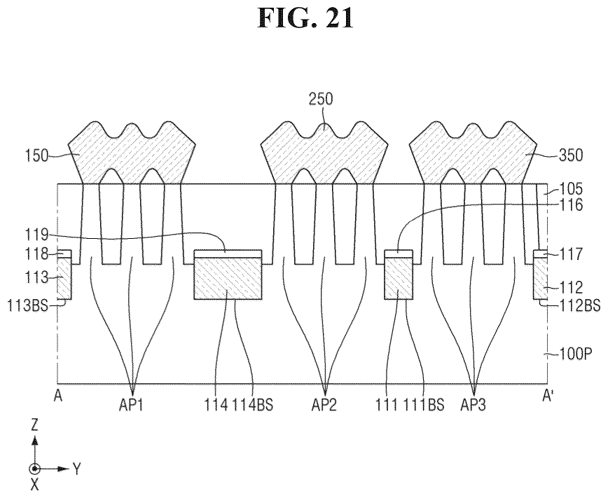

Referring to FIG. 21, the first source/drain pattern 150, the second source/drain pattern 250, and the third source/drain pattern 350 may be formed.

The first source/drain pattern 150 is formed on the first active pattern AP1. The first source/drain pattern 150 may be an epitaxial pattern. The second source/drain pattern 250 is formed on the second active pattern AP2. The second source/drain pattern 250 may be an epitaxial pattern. The third source/drain pattern 350 is formed on the third active pattern AP3. The third source/drain pattern 350 may be an epitaxial pattern.

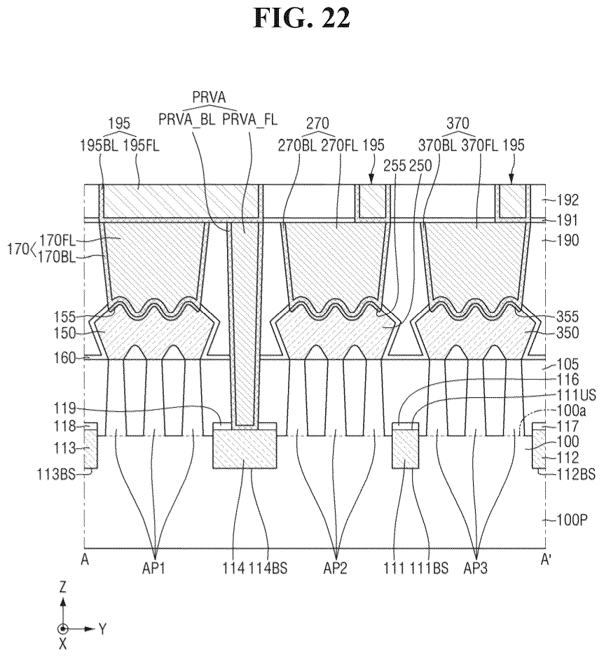

Referring to FIG. 22, the etching stop film 160, the first interlayer insulating film 190, the first source/drain contact 170, the second source/drain contact 270, the third source/drain contact 370, and the power rail via PRVA may be formed.

First, the etching stop film 160 may be formed along the upper surface of the field insulating film 105, the profile of the first source/drain pattern 150, the profile of the second source/drain pattern 250, and the profile of the third source/drain pattern 350. Subsequently, the first interlayer insulating film 190 may be formed on the etching stop film 160.

The first source/drain contact 170, which penetrates the first interlayer insulating film 190 and the etching stop film 160, is formed on the first source/drain pattern 150. Similarly, a second source/drain contact 270, which penetrates the first interlayer insulating film 190 and the etching stop film 160, is formed on the second source/drain pattern 250. A third source/drain contact 370, which penetrates the first interlayer insulating film 190 and the etching stop film 160, is formed on the third source/drain pattern 350. A first contact silicide film 155 is formed at an interface that is between the first source/drain contact 170 and the first source/drain pattern 150. A second contact silicide film 255 is formed at an interface that is between the second source/drain contact 270 and the second source/drain pattern 250. A third contact silicide film 355 is formed at an interface that is between the third source/drain contact 370 and the third source/drain pattern 350.

Subsequently, a power rail via PRVA which penetrates the first interlayer insulating film 190, the etching stop film 160 and the fourth semiconductor pattern 119 may be formed on the fourth semiconductor etching stop pattern 114. The power rail via PRVA may be formed between the first source/drain pattern 150 and the second source/drain pattern 250. The power rail via PRVA may be formed between the first source/drain contact 170 and the second source/drain contact 270.

Next, a lower stop film 191, a second interlayer insulating film 192, and a via plug 195 may be formed on the first source/drain contact 170, the second source/drain contact 270, the third source/drain contact 370, the power rail via PRVA, and the first interlayer insulating film 190.

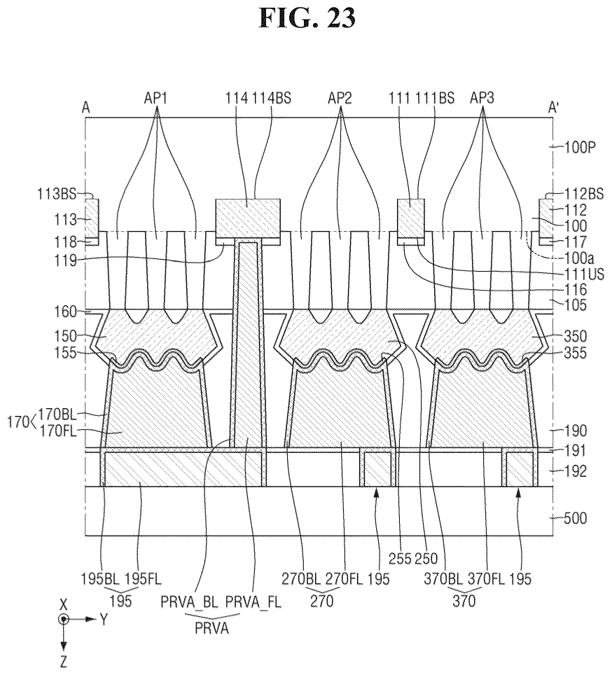

Referring to FIG. 23, a capping substrate 500 may be formed on the second interlayer insulating film 192 and the via plug 195. The capping substrate 500 may be, for example, a glass substrate or a silicon substrate. The semiconductor device may then be rotated by 180 degrees.

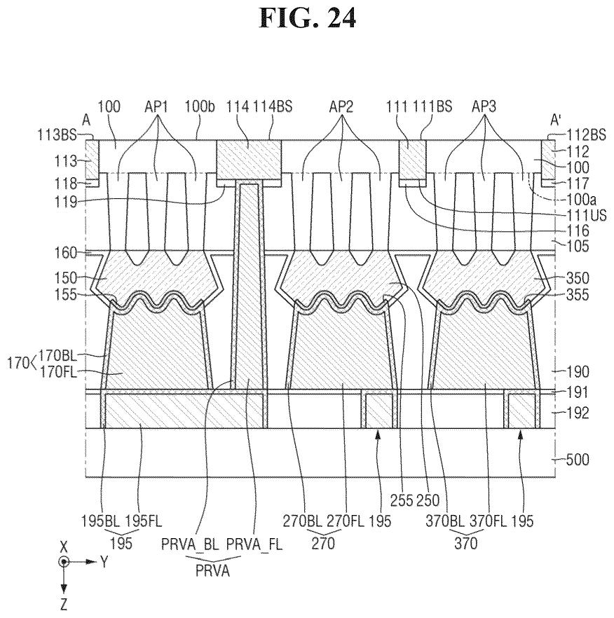

Referring to FIG. 24, the substrate 100 may be formed by etching the pre substrate LOOP. The substrate 100 may include an upper side 100a and a lower side 100b that are opposite to each other.

The first to fourth semiconductor etching stop patterns 111, 112, 113 and 114 may be exposed, by etching the pre substrate 100P.

For example, the pre substrate 100P may be etched through a planarization process (CMP: Chemical Mechanical Polishing). As described above, the pre substrate 100P may have an etching selectivity ratio with respect to the first to fourth semiconductor etching stop patterns 111, 112, 113 and 114. Therefore, when the first to fourth semiconductor etching stop patterns 111, 112, 113, and 114 are exposed while performing the planarization process, the planarization process may be interrupted. Accordingly, the lower side 100b of the substrate 100 may be placed on substantially the same plane as the bottom surfaces 111BS, 112BS, 113BS, and 114BS of the first to fourth semiconductor etching stop patterns 111, 112, 113, and 114.

Since the first to fourth semiconductor etching stop patterns 111, 112, 113, and 114 are placed, the thickness of the substrate 100 may be substantially constant. Therefore, a semiconductor device having increased reliability may be manufactured.

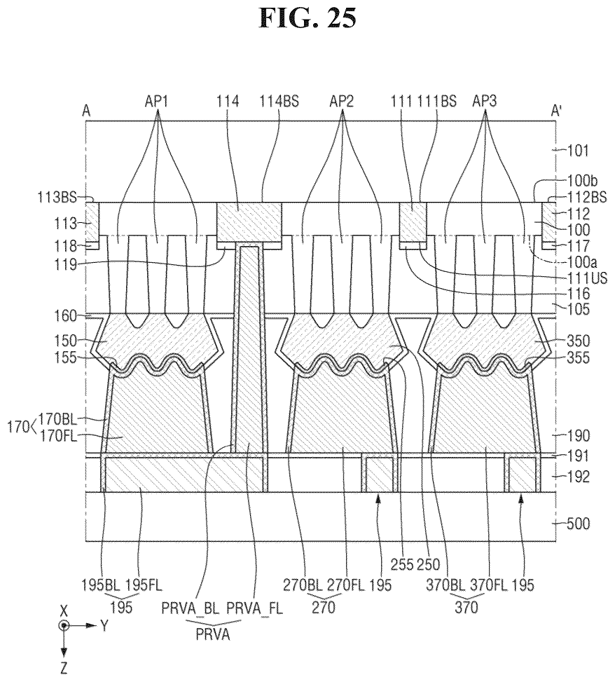

Referring to FIG. 25, a lower insulating film 101 may be formed on the lower side 100b of the substrate 100 and the bottom surfaces 111BS, 112BS, 113BS and 114BS of the first to fourth semiconductor etching stop patterns 111, 112, 113 and 114. The lower insulating film 101 may cover the lower side 100b of the substrate 100 and the bottom surfaces 111BS, 112BS, 113BS, and 114BS of the first to fourth semiconductor etching stop patterns 111, 112, 113, and 114.

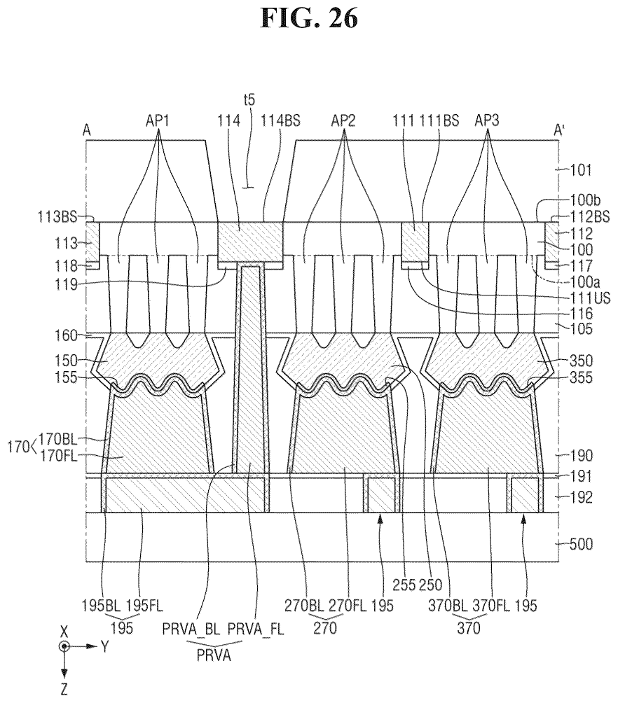

Referring to FIG. 26, a part of the lower insulating film 101 may be etched to form a fifth trench t5. The fifth trench t5 is formed on the fourth semiconductor etching stop pattern 114. The fifth trench t5 may expose the bottom surface 114BS of the fourth semiconductor etching stop pattern 114.

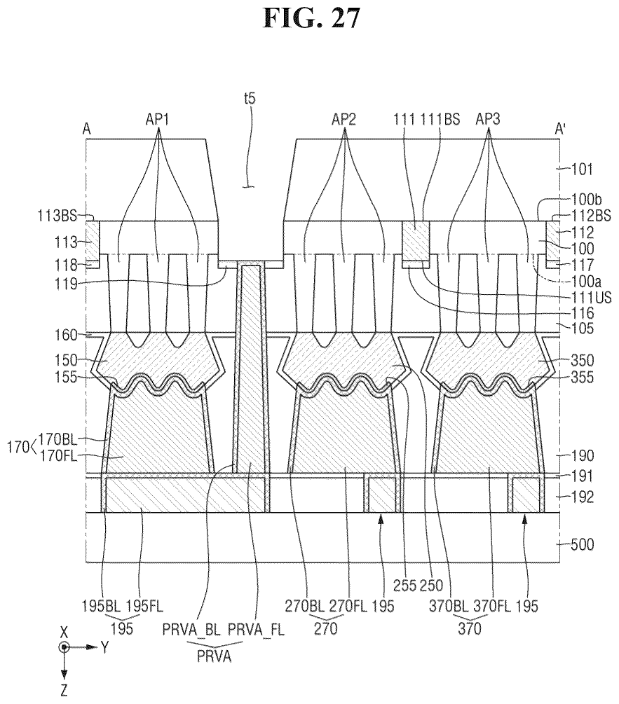

Referring to FIG. 27, the fourth semiconductor etching stop pattern 114 may be removed. The fourth semiconductor etching stop pattern 114 may be removed to expose a part of the substrate 100, the fourth semiconductor pattern 119, and the power rail via PRVA. For example, the fourth semiconductor etching stop pattern 114 may be removed through a wet etching process. As described above, the fourth semiconductor etching stop pattern 114 may have an etching selectivity ratio with respect to the substrate 100. Accordingly, only the fourth semiconductor etching stop pattern 114 may be selectively removed.

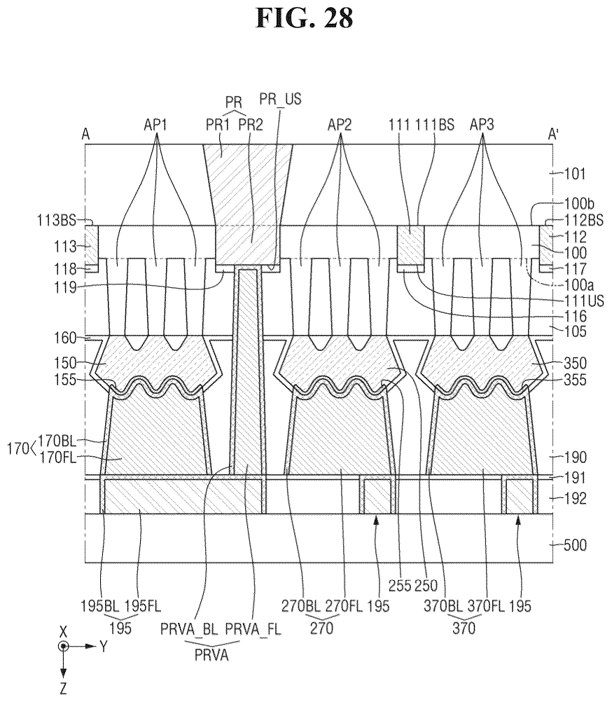

Referring to FIG. 28, a power rail PR, which fills the fifth trench t5, may be formed. The power rail PR includes a via PR2 and a power line PR1. The via PR2 of the power rail PR may be brought into contact with the power rail via PRVA. The power line PR1 may be formed on the via PR2 of the power rail PR. Thereafter, the capping substrate 500 may be removed and the semiconductor device may be rotated by 180 degrees again.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. A semiconductor device comprising:
a substrate which includes an upper side and a lower side that are opposite to each other;
first and second active patterns which each extend in a first direction and are spaced apart from each other in a second direction;
a field insulating film which covers side walls of the first and second active patterns;
a power rail which is disposed adjacent to a first side wall of the second active pattern and between the first active pattern and the second active pattern;
a power rail via which is disposed on the power rail and connected to the power rail;
a semiconductor etching stop pattern which is disposed adjacent to a second side wall of the second active pattern; and
a first semiconductor pattern disposed on the semiconductor etching stop pattern,
wherein a lower surface of the semiconductor etching stop pattern is disposed on a same plane as the lower side of the substrate, and
wherein at least part of the first semiconductor pattern is disposed in the field insulating film.

2. The semiconductor device of claim 1, further comprising:
a plurality of gate electrodes which each extend in the second direction and are spaced apart from each other in the first direction, on the first and second active patterns,
wherein the power rail via is disposed between the plurality of gate electrodes.

3. The semiconductor device of claim 1, further comprising:
a lower insulating film disposed on the lower side of the substrate,
wherein the power rail penetrates the lower insulating film.

4. The semiconductor device of claim 3, wherein the semiconductor etching stop pattern is in contact with the lower insulating film.

5. The semiconductor device of claim 1, wherein an upper surface of the semiconductor etching stop pattern and an upper surface of the power rail are on a same plane.

6. The semiconductor device of claim 1, wherein a first height of the upper surface of the semiconductor etching stop pattern based on the lower side of the substrate is greater than a second height of a lower surface of the power rail via based on the lower side of the substrate.

7. The semiconductor device of claim 1, further comprising:
a second semiconductor pattern disposed on an upper surface of the power rail via,
wherein the power rail via penetrates the second semiconductor pattern and is connected to the power rail.

8. The semiconductor device of claim 7, wherein at least part of the second semiconductor pattern is disposed in the field insulating film.

9. The semiconductor device of claim 7, wherein a thickness of the second semiconductor pattern is equal to a thickness of the first semiconductor pattern.

10. The semiconductor device of claim 1, wherein at least a part of the semiconductor etching stop pattern is disposed in the field insulating film.

11. The semiconductor device of claim 1, wherein the semiconductor etching stop pattern does not completely overlap the field insulating film in the first direction and the second direction.

12. The semiconductor device of claim 1, wherein the semiconductor etching stop pattern and the first semiconductor pattern are formed of different materials from each other.

13. A semiconductor device comprising:
a substrate which includes an upper side and a lower side that are opposite to each other;
a lower insulating film which is disposed on the lower side of the substrate;
first to third active patterns which each extend in a first direction and are sequentially aligned in a second direction;
a field insulating film which covers side walls of the first to third active patterns;
a plurality of gate electrodes which cover the first to third active patterns, and extend in the second direction, wherein the plurality of gate electrodes are spaced apart from each other in the first direction, on the field insulating film;
a first source/drain pattern which is disposed between the plurality of gate electrodes, on the first active pattern;
a second source/drain pattern which is disposed between the plurality of gate electrodes, on the second active pattern;
a power rail which penetrates the lower insulating film and is disposed between the first active pattern and the second active pattern;
a power rail via which is disposed between the plurality of gate electrodes, and between the first source/drain pattern and the second source/drain pattern, wherein the power rail via is disposed on the power rail and is connected to the power rail;
a first semiconductor etching stop pattern which is disposed between the second active pattern and the third active pattern; and
a semiconductor pattern disposed on the first semiconductor etching stop pattern,
wherein a first spaced distance in the second direction between the first active pattern and the second active pattern is greater than a second spaced distance in the second direction between the second active pattern and the third active pattern,
a lower surface of the first semiconductor etching stop pattern is disposed on the lower insulating film, and
at least part of the semiconductor pattern overlaps the field insulating film.

14. The semiconductor device of claim 13, further comprising:
a source/drain contact connected to the first source/drain pattern,
wherein an upper surface of the source/drain contact is disposed on a same plane as an upper surface of the power rail via.

15. The semiconductor device of claim 13, further comprising:
a second semiconductor etching stop pattern which is disposed adjacent to a first side wall of the third active pattern opposite to a second sidewall of the third active pattern that is facing the second active pattern,
wherein a lower surface of the second semiconductor etching stop pattern and a lower surface of the first semiconductor etching stop pattern are disposed on a same plane.

16. The semiconductor device of claim 13, wherein a height of an upper surface of the first semiconductor etching stop pattern based on the upper side of the substrate is greater than a height of a lower surface of the power rail via based on the upper side of the substrate.

17. The semiconductor device of claim 13, wherein the first to third active patterns each include first to third lower patterns, which extend in the first direction, and first to third sheet patterns, which are disposed on each of the first to third lower patterns.

18. The semiconductor device of claim 13, wherein at least a part of the first semiconductor etching stop pattern is disposed in the field insulating film.

19. A semiconductor device comprising:
a substrate which includes an upper side and a lower side that are opposite to each other;
first and second active patterns which include first and second lower patterns, each of which extend in a first direction and are spaced apart from each other in a second direction, and first and second sheet patterns, which are spaced apart from each of the first and second lower patterns in a third direction, on the upper side of the substrate;
a field insulating film which covers side walls of the first and second lower patterns and is disposed on the upper side of the substrate;
a plurality of gate electrodes which wrap around the first and second sheet patterns on the first and second lower patterns, and extend in the second direction, wherein the plurality of gate electrodes are spaced apart from each other in the first direction;
a first source/drain pattern which is connected to the first sheet pattern and is disposed between the plurality of gate electrodes, on the first lower pattern;
a second source/drain pattern which is connected to the second sheet pattern and is disposed between the plurality of gate electrodes, on the second lower pattern;
a power rail which is placed between the first lower pattern and the second lower pattern, on the lower side of the substrate;
a power rail via which is placed between the first and second source/drain patterns and between the plurality of gate electrodes, wherein the power rail via is connected to the power rail;
a semiconductor etching stop pattern which is placed adjacent to a first side wall of the second lower pattern that is opposite to a second sidewall of the second lower pattern that faces the first lower pattern; and
a semiconductor pattern disposed on the semiconductor etching stop pattern,
wherein a lower surface of the semiconductor etching stop pattern is placed on a same plane as the lower side of the substrate,
at least a part of the semiconductor pattern overlaps the field insulating film in the third direction, and
the semiconductor etching stop pattern and the semiconductor pattern are formed of different materials from each other.

20. The semiconductor device of claim 19, further comprising:
a lower insulating film disposed on the lower side of the substrate,
wherein the power rail penetrates the lower insulating film, and
wherein a lower surface of the semiconductor etching stop pattern is in contact with the lower insulating film.
